(19) United States
(12) Patent Application Publication
(10) Pub. No.: US 2025/0183030 A1
(43) Pub. Date: Jun. 5, 2025

(54) METAL AND PHOSPHOROUS CONTAINING FILMS AND METHODS AND SYSTEMS FOR PRODUCING SAID FILMS AND APPLICATIONS THEREOF

(71) Applicant: ASM IP Holding B.V., Almere (NL)

(72) Inventors: Charles Dezelah, Helsinki (FI); Patricio Eduardo Romero, Wilsele (BE); Giuseppe Alessio Verni, Ismaning (DE); Petro Deminiskyi, Espoo (FI); Suvidyakumar Vinod Homkar, Leuven (BE); Ren-Jie Chang, Chandler, AZ (US)

(21) Appl. No.: 18/962,010

(22) Filed: Nov. 27, 2024

Related U.S. Application Data
(60) Provisional application No. 63/604,714, filed on Nov. 30, 2023.

(51) Int. Cl. H01L 21/02; C23C 16/44; C23C 16/455; H10D 64/66; H10D 64/68

(52) U.S. Cl. CPC H01L 21/0228; C23C 16/4408; C23C 16/45553; H01L 21/02192; H10D 64/667; H10D 64/691

(57) ABSTRACT

The present disclosure generally relates to metal and phosphorous containing thin films and methods and systems for forming said films and to semiconductor device structures comprising said films. Exemplary methods for forming the metal and phosphorous containing thin films comprise executing one or more deposition cycles of a cyclic deposition process comprising sequentially exposing at least a portion of a surface of a substrate to a metal precursor and to a phosphorous precursor, thereby forming a metal and phosphorous containing film on the at least a portion of the surface of the substrate. Exemplary semiconductor device structures comprising the metal and phosphorous containing films can include field effect transistor structures, wherein the metal and phosphorous containing film may be useful as a threshold voltage shifting layer.

### CROSS-REFERENCE TO RELATED APPLICATION(S)

This Application claims the benefit of U.S. Provisional Application 63/604,714 filed on Nov. 30, 2023, the entire contents of which are incorporated herein by reference.

### FIELD

The present disclosure generally relates to the field of semiconductor devices. More particularly, the present disclosure generally relates to metal and phosphorous containing thin films and methods and systems for forming said films and to semiconductor devices structures comprising said films.

### BACKGROUND

The scaling of semiconductor devices, such as, for example, complementary metal-oxide-semiconductor (CMOS) devices, has led to significant improvements in the speed and density of integrated circuits. Further scaling of device dimensions for next generation nodes, however, is challenging and will require the use of alternative materials and new processing techniques. For example, one challenge has been finding suitable dielectric stacks that form an insulating barrier between a gate and a channel of a field effect transistor. As scaling continues, the reduced dimensions of the gate cavity will only allow for thin layers of dielectric stack materials, including threshold voltage shifting materials. Thus, methods for achieving very thin films of novel materials for threshold voltage shifting are of a high interest. The present disclosure addresses and meets these needs.

Any discussion, including discussion of problems and solutions, set forth in this section has been included in this disclosure solely for the purpose of providing a context for the present disclosure. Such discussion should not be taken as an admission that any of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

The present disclosure relates to metal and phosphorous containing films and to methods and systems for forming said films and to semiconductor devices structures comprising said films. The metal and phosphorous containing films may beneficially be used as a threshold voltage shifting layer in a gate stack of a field effect transistor (FET).

An aspect of the present disclosure is related to films of a metal and phosphorus containing material. The metal and phosphorus containing film may be position on or over at least a portion of a surface of a substrate, either directly on the surface of the substrate or on one or more other layers on the substrate, or it may be interposed between two or more other layers that are on the substrate.

Another aspect of the present disclosure is related to structures comprising a substrate and a threshold voltage shifting layer comprising a metal and phosphorus containing material. In some embodiments, the structure can be or form part of a gate stack, wherein the gate stack comprises the threshold voltage shifting layer. In some embodiments, the structure can be or form part of a field effect transistor (FET). In some embodiments the structure can be or form part of a CMOS device.

Another aspect of the present disclosure is related to methods for forming a film of a metal and phosphorus containing material. The methods for forming a film of a metal and phosphorus containing material may be used to form a structure comprising a threshold voltage shifting layer comprising a metal and phosphorus containing material. Thus, the present disclosure is additionally related to methods for forming a semiconductor device structure comprising a threshold voltage shifting layer that comprises a metal and phosphorus containing material. The methods comprise providing a substrate in a reaction space and executing one or more deposition cycles of a cyclic deposition process comprising exposing at least a portion of a surface of the substrate to one of a metal precursor and a phosphorous precursor, and exposing the at least a portion of the surface of the substrate to the other of the metal precursor and the phosphorus precursor, thereby forming a metal and phosphorous containing film on the at least a portion of the surface of the substrate. The cyclic deposition process may further comprise, purging the reaction space between the exposing steps.

In some embodiments, the method for forming the metal and phosphorus containing film further comprises, exposing the at least a portion of the surface of the substrate to a halogen reactant. In some embodiments, at least one of the one or more deposition cycles of the cyclic deposition process further comprises: exposing the at least a portion of the surface of the substrate to a halogen reactant. In some embodiments, the one or more deposition cycles further comprises: exposing the at least a portion of the surface of the substrate to a halogen reactant, wherein the exposing of the at least a portion of the surface of the substrate to the halogen reactant occurs after the exposing of the at least a portion of the surface of the substrate to the metal precursor and prior to the exposing of the at least a portion of the surface of the substrate to the phosphorus precursor.

In some embodiments, the method for forming the metal and phosphorus containing film further comprises exposing the at least a portion of the surface of the substrate to an oxygen reactant. In some embodiments, at least one of the one or more deposition cycles of the cyclic deposition process further comprises exposing the at least a portion of the surface of the substrate to an oxygen reactant.

In some embodiments, the method further comprises maintaining a temperature of the substrate at an elevated temperature. In some embodiments, the temperature of the substrate is maintained at least about 40° C. to no more than about 500° C., or at least about 100° C. to no more than about 450° C., or at least about 100° C. to no more than about 400° C., or at least about 100° C. to no more than about 350° C., or at least about 200° C. to no more than about 450° C., or at least about 200° C. to no more than about 400° C., or at least about 200° C. to no more than about 350° C.

In some embodiments, the method is performed under thermal conditions. In these embodiments, the deposition process does not include use of a plasma to form activated species. For example, the cyclic deposition process may not comprise the use of plasma, may not comprise the formation or use of excited species, and/or may not comprise the formation or use of radicals in any of the process steps.

In some embodiments, the method further comprises annealing the substrate comprising the metal and phosphorous containing film. The annealing may be performed by heating the substrate comprising the metal and phosphorous containing film to an annealing temperature from at least about 300° C. to no more than about 1,200° C. for a set period of time. In some of these embodiments, annealing is performed by heating the substrate comprising the metal and phosphorous containing film to an annealing temperature from at least about 600° C. to no more than about 1,200° C. In other embodiments, annealing is performed by heating the substrate comprising the metal and phosphorous containing film to an annealing temperature from at least about 300° C. to no more than about 600° C.

Another aspect of the present disclosure is related to systems, such as, for example, a semiconductor processing apparatus, for forming a film of a metal and phosphorus containing material. The system for forming a film of a metal and phosphorus containing material may be used to form a structure comprising a threshold voltage shifting layer comprising a metal and phosphorus containing material. Thus, the present disclosure is additionally related to systems for forming a semiconductor device structure comprising a threshold voltage shifting layer that comprises a metal and phosphorus containing material. In some embodiments, the system comprises, a reaction space for accommodating a substrate; a metal precursor source for providing a metal precursor in gas communication via a metal precursor source valve with the reaction space; a phosphorous precursor source for providing a phosphorous precursor in gas communication via a phosphorous precursor source valve with the reaction space; an exhaust; and a controller operably connected to the metal precursor source valve and the phosphorous precursor source valve, wherein the controller is configured and programmed to perform at least one deposition cycle of a cyclic deposition process. The controller may be configured and programmed to perform at least one deposition cycle of a cyclic deposition process by sequentially controlling: opening one of the metal precursor source valve to the metal precursor source and the phosphorous precursor source valve to the phosphorous precursor source; closing the one of the metal precursor source valve to the metal precursor source and the phosphorous precursor source valve to the phosphorous precursor source; opening the other of the metal precursor source valve to the metal precursor source and the phosphorous precursor source valve to the phosphorous precursor source; and closing the other of the metal precursor source valve to the metal precursor source and the phosphorous precursor source valve to the phosphorous precursor source.

In some embodiments, the system further comprises a halogen reactant source for providing a halogen reactant in gas communication via a halogen reactant source valve with the reaction space and the controller is further operably connected to the halogen reactant source valve and configured and programmed to control: opening the halogen reactant source valve to the halogen reactant source; and closing the halogen reactant source valve to the halogen reactant source. In some embodiments, the controller is further programed to, after at least one of the closing of the metal precursor source valve to the metal precursor source or after at least one of the closing of the phosphorous precursor source valve to the phosphorous precursor source, open the halogen reactant source valve to the halogen reactant source and close the halogen reactant source valve to the halogen reactant source. In some embodiments, the controller is further programed to, after each of the closing of the metal precursor source valve to the metal precursor source, open the halogen reactant source valve to the third and then close the halogen reactant source valve to the halogen reactant source.

In some embodiments, the system further comprises an oxygen reactant source for providing an oxygen reactant in gas communication via an oxygen reactant source valve with the reaction space and the controller is further operably connected to the oxygen reactant source valve and configured and programmed to control: opening the oxygen reactant source valve to the oxygen reactant source; and closing the oxygen reactant source valve to the oxygen reactant source. In some embodiments, the controller is further programed to, after at least one of the closing of the metal precursor source valve to the metal precursor source or after at least one of the closing of the phosphorous precursor source valve to the phosphorous precursor source, open the oxygen reactant source valve to the oxygen reactant source and close the oxygen reactant source valve to the oxygen reactant source.

In some embodiments, the system further comprises one or more heating elements and one or more thermocouples and the controller is further operably connected to the one or more heating elements and to the one or more thermocouples and configured and programmed to measure and control a temperature of the at least one heating element to maintain a temperature of the substrate at an elevated temperature. In some embodiments, the temperature of the substrate is maintained at least about 40° C. to no more than about 500° C., or at least about 100° C. to no more than about 450° C., or at least about 100° C. to no more than about 400° C., or at least about 100° C. to no more than about 350° C., or at least about 200° C. to no more than about 450° C., or at least about 200° C. to no more than about 400° C., or at least about 200° C. to no more than about 350° C.

In the aspects of the above disclosure that are related to the methods and the systems, in some embodiments, the phosphorous precursor is selected from the group consisting of phosphine (PH₃), tetraphosphorus (P₄), 1,2-diphosphinoethane (C₂H₈P₂), methyl phosphine (PH₂Me), trimethyl phosphine (PMe₃), ethyl phosphine (PH₂Et), triethyl phosphine (PEt₃), isopropylphosphine (PH₂ⁱPr), i-butylphosphine (PH₂ⁱBu), t-butylphosphine (PH₂ⁿBu), dichloromethylphosphine (MePCl₂), dichloroethylphosphine (PCl₂Et), dichloropropylphosphine (PCl₂ⁿPr), dichloroisopropylphosphine (PCl₂ⁱPr), dichlorobutylphosphine (PCl₂ⁿBu), dichlorotertbutylphosphine (PCl₂^{t}Bu), chloro(diisopropyl)phosphine (PClⁱPr₂), chloro(dimethyl)phosphine (PClMe₂), chloro(diethyl)phosphine (PClEt₂), chloro (di-secbutyl) phosphine (PCl^{s}Bu₂), chloro(di-tertbutyl)phosphine (PCl^{t}Bu₂), bromo(di-secbutyl)phosphine (PBr^{t}Bu₂), chloro(tertbutyl)(methyl)phosphine (PCl^{t}BuMe), cyclohexylphosphine (PH₂(C₆H₁₁), phenyl phosphine (PH₂Ph), 1,2-diphosphinobenzene, tris(₁-pyrrolidinyl)phosphine (P(C₄H₈N)₃), dimethylaminophosphine (PH₂(NMe₂)₂), bis(dimethylamino)phosphine (PH(NMe₂), dimethylamino(methyl)phosphine (PMe(NMe₂)₂), tris(dimethylamino)phosphine (P(NMe₂)₃), tris(diethylamino)phosphine (P(NEt₂)₃), chlorobis(dimethylamino)phosphine (PCl(NMe₂)₂), dichloro(dimethylamino)phosphine (PCl₂(NMe₂)), dichloro(diethylamino)phosphine (PCl₂(NEt₂)), chlorobis(diethylamino)phosphine (PCl(NEt₂)₂), chlorobis(diisopropylamino)phosphine (PCl(NⁱPr₂)₂), dichloro(diisopropylamino)phosphine (PCl₂(NⁱPr₂)), tris(dimethylamino)phosphine (P(NMe₂)₃), trisilylphosphine (P(SiH₃)₃), tris(trimethylsilyl)phosphine (P(SiMe₃)₃), tris(triethylsilyl)phosphine (P(SiEt₃)₃), tris(trimethylsiloxy)phosphine (P(OSiMe₃)₃), trimethyl phosphite (POMe₃), trimethyl phosphate (P(O)OMe₃), phosphorus pentoxide (P₂O₅), phosphorous trichloride (PCl₃), phosphorous tribromide (PBr₃), phosphorous triiodide (PI₃), phosphorous pentachloride (PCl₅), phosphorous pentabromide (PBr₅), phosphoryl chloride (POCl₃), phosphoryl bromide (POBr₃), and combinations thereof.

In the aspects of the above disclosure that are related to the methods and the systems, in some embodiments, the metal precursor comprises a metal and one or more ligands selected from the group consisting of a halide, a carbonyl, an oxo, an alkyl, a cyclopentadienyl, η⁶-arene, an alkoxide, an imido, an alkyl amide, a silyl amide, a β-diketonate, an amidinate, a diazadiene, and a triazenide.

In the aspects of the above disclosure that are related to the methods and the systems, in some embodiments, the halogen reactant is selected from the group consisting of carbon tetrafluoride (CF₄), carbon tetrachloride (CCl₄), carbon tetrabromide (CBr₄), bis(trichloromethyl)carbonate (C₃Cl₆O₃), diiodomethane (CH₂I₂), diiodoethane (C₂H₄I₂), acetyl chloride (CH₃COCl), oxalyl chloride (CO₂Cl₂), sulfur tretrafluoride (SF₄), sulfur hexafluoride (SF₆), sulfur dichloride (SCl₂), disulfur dichloride (S₂Cl₂), thionyl chloride (SOCl₂), sulfuryl chloride (SO₂Cl₂), xenon difluoride (XeF₂), selenium tetrafluroride (SeF₄), selenium hexafluroride (SeF₆), selenium dichloride (SeCl₂), selenium tetrachloride (SeCl₄), diselenium dichloride (Se₂Cl₂), tellurium hexafluoride (TeF₆), silicon tetrachloride (SiCl₄), antimony pentafluoride (SbF₅), antimony trichloride (SbCl₃), antimony pentachloride (SbCl₅), boron trichloride (BCl₃), germanium tetrachloride (GeCl₄), nitrogen trifluoride (NF₃), nitrogen chloride fluoride (NCl₂F and/or NF₂Cl), nitrosyl fluoride (NOF), nitryl fluoride (NO₂F), phosphorous trichloride (PCl₃), phosphorous pentachloride (PCl₅), phosphoryl chloride (POCl₃), phosphorous tribromide (PBr₃), phosphorous pentabromide (PBr₅), phosphoryl bromide (POBr₃), hydrogen fluoride (HF), hydrogen chloride (HCl), fluorine (F₂), chlorine (Cl₂), bromine (Br₂), titanium tetrafluoride (TiF₄), titanium tetrachloride (TiCl₄), tungsten hexafluoride (WF₆), niobium pentafluoride (NbF₅), and niobium pentachloride (NbCl₅). In some embodiments, the halogen reactant comprises chlorine.

In the aspects of the above disclosure that are related to the methods and the systems, in some embodiments, the oxygen reactant is selected from the group consisting of oxygen, ozone, water, hydrogen peroxide, an organic peroxide, an alcohol, nitrogen dioxide, nitrous oxide, nitric oxide, dinitrogen pentoxide, pyridine oxide, an amine oxide, and combinations thereof. In some embodiments, the oxygen containing reactant is oxygen, ozone, nitrous oxide, or a combination thereof.

In the aspects of the above disclosure, in some embodiments, the metal and phosphorous containing material comprises a metal selected from a rare earth metal, a group 4 metal, a group 5 metal, a group 6 metal, a group 13 metal, and combinations thereof. In some embodiments, the metal in the metal and phosphorous containing material is selected from the group consisting of scandium, yttrium, lanthanum, cerium, praseodymium, neodymium, promethium, samarium, europium, gadolinium, terbium, dysprosium, holmium, erbium, thulium, ytterbium, lutetium, titanium, zirconium, hafnium, vanadium, niobium, tantalum, chromium, molybdenum, tungsten, boron, aluminum, gallium, indium, and combinations thereof.

In the aspects of the above disclosure, in some embodiments, the metal and phosphorous containing material comprises a metal phosphide material. In some embodiments, the metal and phosphorous containing material is a metal phosphide material. The metal phosphide material may be selected from a rare earth metal phosphide, a group 4 metal phosphide, a group 5 metal phosphide, a group 6 metal phosphide, a group 13 metal phosphide, and combinations thereof.

In the aspects of the above disclosure, in some embodiments, the metal and phosphorus containing material comprises a rare earth metal phosphide. In some embodiments, the metal and phosphorus containing material is a rare earth metal phosphide. The rare earth metal phosphide may be selected from the group consisting of scandium phosphide, yttrium phosphide, lanthanum phosphide, cerium phosphide, praseodymium phosphide, neodymium phosphide, promethium phosphide, samarium phosphide, europium phosphide, gadolinium phosphide, terbium phosphide, dysprosium phosphide, holmium phosphide, erbium phosphide, thulium phosphide, ytterbium phosphide, lutetium phosphide, and combinations thereof. In some embodiments, rare earth metal phosphide may be selected from the group consisting of scandium phosphide, yttrium phosphide, lanthanum phosphide, cerium phosphide, and combinations thereof.

In the aspects of the above disclosure, in some embodiments, the metal and phosphorus containing material comprises a group 4 metal phosphide. In some embodiments, the metal and phosphorus containing material is a group 4 metal phosphide. The group 4 metal phosphide may be selected from the group consisting of vanadium phosphide, niobium phosphide, tantalum phosphide, and combinations thereof.

In the aspects of the above disclosure, in some embodiments, the metal and phosphorus containing material comprises a group 5 metal phosphide. In some embodiments, the metal and phosphorus containing material is a group 5 metal phosphide. The group 5 metal phosphide may be selected from the group consisting of titanium phosphide, zirconium phosphide, hafnium phosphide, and combinations thereof.

In the aspects of the above disclosure, in some embodiments, the metal and phosphorus containing material comprises a group 6 metal phosphide. In some embodiments, the metal and phosphorus containing material is a group 6 metal phosphide. The group 6 metal phosphide may be selected from the group consisting of chromium phosphide, molybdenum phosphide, tungsten phosphide, and combinations thereof.

In the aspects of the above disclosure, in some embodiments, the metal and phosphorus containing material comprises a group 13 metal phosphide. In some embodiments, the metal and phosphorus containing material is a group 13 metal phosphide. The group 13 metal phosphide may be selected from the group consisting of boron phosphide, aluminum phosphide, gallium phosphide, indium phosphide, and combinations thereof.

In the aspects of the above disclosure, in certain embodiments, the metal and phosphorous containing material further comprises oxygen. In some of these embodiments, the metal and phosphorous containing material is a metal phosphide material that further comprises oxygen or a metal oxyphosphide material. The metal oxyphosphide material may be selected from a rare earth metal oxyphosphide, a group 4 metal oxyphosphide, a group 5 metal oxyphosphide, a group 6 metal oxyphosphide, a group 13 metal oxyphosphide, and combinations thereof.

In the aspects of the above disclosure, in some embodiments, the metal and phosphorus containing material comprises a rare earth metal oxyphosphide. In some embodiments, the metal and phosphorus containing material is a rare earth metal oxyphosphide. The rare earth metal phosphide may be selected from the group consisting of scandium oxyphosphide, yttrium oxyphosphide, lanthanum oxyphosphide, cerium oxyphosphide, praseodymium poxyhosphide, neodymium oxyphosphide, promethium oxyphosphide, samarium oxyphosphide, europium oxyphosphide, gadolinium oxyphosphide, terbium oxyphosphide, oxydysprosium phosphide, holmium oxyphosphide, erbium oxyphosphide, thulium oxyphosphide, ytterbium oxyphosphide, lutetium oxyphosphide, and combinations thereof. In some embodiments, rare earth metal phosphide may be selected from the group consisting of scandium oxyphosphide, yttrium oxyphosphide, lanthanum oxyphosphide, cerium oxyphosphide, and combinations thereof

In the aspects of the above disclosure, in some embodiments, the metal and phosphorus containing material comprises a group 4 metal oxyphosphide. In some embodiments, the metal and phosphorus containing material is a group 4 metal oxyphosphide. The group 4 metal oxyphosphide may be selected from the group consisting of vanadium oxyphosphide, niobium oxyphosphide, tantalum oxyphosphide, and combinations thereof.

In the aspects of the above disclosure, in some embodiments, the metal and phosphorus containing material comprises a group 5 metal oxyphosphide. In some embodiments, the metal and phosphorus containing material is a group 5 metal oxyphosphide. The group 5 metal oxyphosphide may be selected from the group consisting of titanium oxyphosphide, zirconium oxyphosphide, hafnium oxyphosphide, and combinations thereof.

In the aspects of the above disclosure, in some embodiments, the metal and phosphorus containing material comprises a group 6 metal oxyphosphide. In some embodiments, the metal and phosphorus containing material is a group 6 metal oxyphosphide. The group 6 metal oxyphosphide may be selected from the group consisting of chromium oxyphosphide, molybdenum oxyphosphide, tungsten oxyphosphide, and combinations thereof.

In the aspects of the above disclosure, in some embodiments, the metal and phosphorus containing material comprises a group 13 metal oxyphosphide. In some embodiments, the metal and phosphorus containing material is a group 13 metal oxyphosphide. The group 13 metal oxyphosphide may be selected from the group consisting of boron oxyphosphide, aluminum oxyphosphide, gallium oxyphosphide, indium oxyphosphide, and combinations thereof.

In the aspects of the above disclosure, in some embodiments, the metal and phosphorus containing film comprises a metal phosphide material or a metal oxyphosphide material comprising a metal selected from the group consisting of a rare earth metal, titanium (Ti), zirconium (Zr), hafnium (Hf), niobium (Nb), tantalum (Ta), chromium (Cr), tungsten (W), and mixtures thereof.

In the aspects of the above disclosure, in certain embodiments, the metal and phosphorous containing material is free or substantially free of oxygen. In some embodiments, an oxygen content of the metal and phosphorous containing material is less than about 5.0% (atomic %), or less than about 1.0%, or less than about 0.1%.

In the aspects of the above disclosure, in some embodiments, the metal and phosphorous containing material is free or substantially free of carbon. In some embodiments, a carbon content of the metal and phosphorous containing material is less than about 5.0% (atomic %), or less than about 1.0%, or less than about 0.1%.

In the aspects of the above disclosure, in some embodiments, the metal and phosphorous containing material is free or substantially free of non-phosphide phosphorous. In some embodiments, a non-phosphide phosphorous content of the metal and phosphorous containing material is less than about 5.0% (atomic %), or less than about 1.0%, or less than about 0.1%.

In the aspects of the above disclosure, in some embodiments, the film of the metal and phosphorous containing material has a thickness of about 0.01 nm or more to about 2 nm or less, typically about 0.01 nm or more to about 1 nm or less. In some embodiments, the thickness is about 2 nm or less, or about 1 nm or less, or about 0.5 nm or less, or about 0.1 nm or less.

In the aspects of the above disclosure, in certain embodiments, the substrate comprises a threshold voltage shifting layer that comprises a metal and phosphorous containing material and at least one of an interlayer and a high-κ dielectric layer. In some embodiments, the substrate comprises the interlayer, and the threshold voltage shifting layer is formed on the interlayer. The threshold voltage shifting layer may be formed directly on the interlayer. In other embodiments, the substrate comprises the high-κ dielectric layer, and the threshold voltage shifting layer is formed on the high-dielectric layer. The threshold voltage shifting layer may be formed directly on the high-κ dielectric layer. In some embodiments, the substrate comprises one or more work function layers or metal layers and the threshold voltage shifting layer is formed on or over at least a portion of the one or more work function layers or metal layers, in some instance the metal and the threshold voltage shifting layer is formed directly on or over at least a portion of one of the one or more work function layers or metal layers.

These and other embodiments will become readily apparent to those skilled in the art from the following detailed description of certain embodiments having reference to the attached figures. The invention is not being limited to any particular embodiments disclosed.

### BRIEF DESCRIPTION OF DRAWINGS

The accompanying drawings constitute part of the specification. The drawings are included to provide a further understanding of the disclosure, and together with the description explain certain principles of the disclosure. The drawings illustrate exemplary embodiments of how the disclosure can be made and used and are not to be construed as limiting the disclosure to only the illustrated and described examples. It will be appreciated that elements in the figures are illustrated for simplicity and clarity and have not necessarily been drawn to scale. The illustrations presented herein are not meant to be actual views of any particular material, structure, or device, but are merely idealized representations that are used to describe embodiments of the disclosure. For example, the dimensions of some of the elements in the figures may be exaggerated relative to other elements to help improve understanding of illustrated embodiments of the present disclosure. Further features and advantages will become apparent from the following, more detailed, description of various aspects, embodiments, and configurations of the disclosure, as illustrated by the drawings referenced below.

FIG. 1 is a process diagram of a cycle deposition process 100 according to an embodiment of the present disclosure, wherein a deposition cycle of the cyclic deposition process comprises, contacting at least a portion of a surface of a substrate with one of a metal precursor and a phosphorous precursor 101, then contacting the at least a portion of the surface of the substrate with the other of the metal precursor and the phosphorus precursor 103. Other optional steps are shown by the dashed lines.

FIG. 2 is a process diagram of a cycle deposition process 200 according to an embodiment of the present disclosure, wherein a deposition cycle of the cyclic deposition process comprises, contacting at least a portion of a surface of a substrate with a metal precursor 201, a halogen reactant 203, and a phosphorous precursor 205. Other optional steps are shown by the dashed lines.

FIG. 3 is a process diagram of a cycle deposition process 300 according to an embodiment of the present disclosure, wherein a deposition cycle of the cyclic deposition process comprises, contacting at least a portion of a surface of a substrate with a phosphorous precursor 301, a metal precursor 303, and a halogen reactant 305. Other optional steps are shown by the dashed lines.

FIG. 4 is a process diagram of a cycle deposition process 400 according to an embodiment of the present disclosure, wherein a deposition cycle of the cyclic deposition process comprises, contacting at least a portion of a surface of a substrate with one of a metal precursor and a phosphorous precursor 401, then contacting the at least a portion of the surface of the substrate with the other of the metal precursor and the phosphorus precursor 403. The cyclic deposition process may further comprise, optionally contacting the at least a portion of the surface of the substrate with a halogen reactant 405. Other optional steps are shown by the dashed lines.

FIG. 5 is a process diagram of a cycle deposition process 500 according to an embodiment of the present disclosure, wherein a deposition cycle of the cyclic deposition process comprises, contacting at least a portion of a surface of a substrate with one of a metal precursor and a phosphorous precursor 501, then contacting the at least a portion of the surface of the substrate with the other of the metal precursor and the phosphorus precursor 503. The cyclic deposition process may further comprise, optionally contacting the at least a portion of the surface of the substrate with an oxygen reactant 505. Other optional steps are shown by the dashed lines.

FIG. 6 is a process diagram of a cycle deposition process 600 according to an embodiment of the present disclosure, wherein a deposition cycle of the cyclic deposition process comprises contacting at least a portion of a surface of a substrate with a metal precursor 601, a halogen reactant 603, and a phosphorous precursor 605. The cyclic deposition process may further comprise, optionally contacting the at least a portion of the surface of the substrate with an oxygen reactant 607. Other optional steps are shown by the dashed lines.

FIG. 7 is a process diagram of a cycle deposition process 700 according to an embodiment of the present disclosure, wherein a deposition cycle of the cyclic deposition process comprises, contacting at least a portion of a surface of a substrate with a phosphorous precursor 701, a metal precursor 703, and a halogen reactant 705. The cyclic deposition process further comprises, optionally contacting the at least a portion of the surface of the substrate with an oxygen reactant 707. Other optional steps are shown by the dashed lines.

FIG. 8 is a process diagram of a cycle deposition process 800 according to an embodiment of the present disclosure, wherein a deposition cycle of the cyclic deposition process comprises, contacting at least a portion of a surface of a substrate with one of a metal precursor and a phosphorous precursor 801, then contacting the at least a portion of the surface of the substrate with the other of the metal precursor and the phosphorus precursor 803. The cyclic deposition process may further comprise, optionally contacting the at least a portion of the surface of the substrate with one of a halogen reactant and an oxygen reactant 805 and then optionally contacting the at least a portion of the surface of the substrate with the other of the halogen reactant and the oxygen reactant 807. Other optional steps are shown by the dashed lines.

FIG. 9 is a schematic presentation of a semiconductor processing apparatus 900 according to an embodiment of the present disclosure.

### DETAILED DESCRIPTION

The description of embodiments of compositions, methods, systems, and structures provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. Unless otherwise noted, the exemplary embodiments or components thereof may be combined or may be applied separate from each other. The headings provided herein, if any, are for convenience only and do not necessarily affect the scope or meaning of the claimed invention.

### Definitions

As used herein, “atomic layer deposition”, abbreviated as “ALD”, refers to a vapor deposition process in which deposition cycles, such as a plurality of consecutive deposition cycles, are conducted in a reaction space (i.e., one or more reaction chambers). Generally, in ALD processes, during each deposition cycle, a precursor is introduced to a reaction space and is adsorbed onto a substrate surface, which may include a previously deposited material from a previous deposition cycle or other materials, forming maximally one monolayer of the precursor that does not readily react with additional excess precursor (i.e., a self-limiting reaction). Thereafter, in some cases, another precursor or a reactant may be introduced into the reaction space to convert the adsorbed precursor to the desired material on the substrate surface. ALD, as used herein, may also be meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of reactants.

As used herein, a “cyclic deposition process” refers to a method or a process comprising sequentially introducing reactants into a reaction space to deposit a layer or a film on or over a substrate and includes processing techniques such as atomic layer deposition (ALD), cyclical chemical vapor deposition (cyclical CVD), and hybrid cyclical deposition processes that include an ALD component and a cyclical CVD component. In preferred embodiments, a cyclic deposition process as disclosed herein refers to an atomic layer deposition process.

As used herein, a “film” or “layer”, which may be used interchangeably, refers to a continuous, substantially continuous, or non-continuous material that extends in a direction perpendicular to a thickness direction to cover at least a portion of a surface. A film may be positioned on a lateral surface and/or on a sidewall of recessed features of a surface. A film can include two-dimensional materials, three-dimensional materials, nanoparticles, partial or full molecular layers, partial or full atomic layers, and/or clusters of atoms or molecules. A film may be built up from one or more non-discernable monolayers or sub-monolayers to produce a uniform or a substantially uniform material, wherein the number of monolayers or sub-monolayers influences the thickness of the material.

As used herein, a “gas” refers to a state of mater consisting of atoms or molecules that have neither a defined volume nor shape. A gas includes vaporized solid and/or liquid and may be constituted by a single gas or a mixture of gases, depending on the context.

As used herein, the term “independently” when used in the context of describing one or more substituent groups (which may be represented as “R”) means that a given R group is independently selected relative to other R groups bearing the same or different subscripts or superscripts and to those lacking a subscript or superscript, but is also independently selected relative to any additional species of that same R group. For example, in the formula CRₙ(NR₂)₄₋ₙ, where n is 0, 1, 2, or 3 and each R is an independently selected substituent, it should be understood that each R group may be distinct or two or more R groups may be identical to each other. More specifically, where n=3, the formula may be written as C(R¹)(R²)(R³)(NR⁵R⁶), and each of R¹, R², R³, R⁴, R⁵, and R⁶ may be distinct from one another or two or more of R¹, R², R³, R⁴, R⁵, and R⁶ may be identical to each other while the others are distinct from one another.

As used herein, a “precursor” refers to a compound that participates in a chemical reaction to form another compound or element, wherein a portion of the precursor (an element or group within the precursor) is incorporated into the compound or element that results from the chemical reaction. The compound or element that results from the chemical reaction may be a layer and/or a film that is formed on a surface of a substrate.

As used herein, a “reactant” refers to a compound that participates in a chemical reaction to form another compound or element. In some instances, a reactant is a precursor. In other instances, the compound or element that results from the chemical reaction does not contain a portion of the reactant (an element or group within the reactant) and therefore the reactant is not a precursor.

As used herein, a “substrate” refers to an underlying material or materials that may be used to form, or upon which, a device, a circuit, a material, or a material layer may be formed. The substrate may be continuous or non-continuous; rigid or flexible; solid or porous; and combinations thereof. The substrate may be in any form, such as, for example, a powder, a sheet, a plate, or a workpiece. Substrates in the form a sheet may extend beyond the bounds of a process/reaction chamber where a deposition process occurs and, in some cases, move through the chamber such that the process continues until the end of the substrate is reached. Substrates in the form of a plate may include wafers in various shapes and sizes. Substrates may be made from semiconductor materials, including, for example, silicon, silicon germanium, silicon oxide, gallium arsenide, gallium nitride, and silicon carbide. A substrate can include one or more layers overlying a bulk material, for example the substrate may include nitrides, for example TiN, oxides, insulating materials, dielectric materials, conductive materials, metals, such as tungsten, ruthenium, molybdenum, cobalt, aluminum, or copper, or other metallic materials, crystalline materials, epitaxial, heteroepitaxial, and/or single crystal materials. The substrate can include various topologies, such as, for example, gaps, recesses, lines, trenches, vias, holes, or spaces between elevated portions, such as fins, and the like formed within or on at least a portion of a layer of the substrate.

As used herein, a “structure” can be or includes a substrate as described herein. Structures can include one or more layers overlying the substrate, such as one or more layers formed according to a method as described herein. Device portions can be or include structures. Likewise, intermediate device portions can be or include structures.

As used herein, a “substituent” refers to an atom or a group of atoms that replaces one or more atoms (such as a hydrogen atom) or a group of atoms in a parent compound, thereby becoming a new group in the resultant new compound. The substituent is substituted for the original atom or a group of atoms in the parent molecule. For simplicity, a substituent may be indicated in a chemical formula as an “R” group and each “R” group in a compound may be independently selected. Examples of substituent groups include, but are not limited to: a hydrogen atom (H); an “alkyl group”, having a general formula of CₙH₂ₙ₊₁ where n is an integer, such as a saturated linear or branched C₁ to C₁₀ alkyl group, preferably C₁ to C₄ alkyl group (e.g., methyl (Me), ethyl (Et), n-propyl (ⁿPr), iso-propyl (^{I}Pr), n-butyl (ⁿBu), i-butyl (ⁱBu), sec-butyl (^{s}Bu), and tert-butyl (^{t}Bu)); a “cycloalkyl group”, having a general formula of CₙH₂ₙ₋₁ where n is an integer, such as C₃ to C₆ cyclic alkyl groups (e.g., cyclopropyl, cyclobutyl, cyclopentyl, and cyclohexyl); an “alkenyl group”, such as C₂ to C₆ linear or branched unsaturated hydrocarbons less one hydrogen atom (e.g., vinyl, allyl, propenyl, butenyl, pentenyl, hexenyl, butadienyl, pentadienyl, hexadienyl, ethynyl, propargyl, butynyl, pentynyl, and hexynyl); an “aryl group”, such as a phenyl, benzyl, tolyl, xylyl, naphthyl, cyclopentadienyl (Cp), and methyl, dimethyl, or ethyl cyclopentadienyl groups; a hydroxy group (OH); an “alkoxy group” having a general formula of CₙH₂ₙ₊₁O where n is an integer, such as a linear or branched C₁ to C₁₀ alkoxy group, typically a C₁ to C₄ alkoxy group (e.g., methoxy, ethoxy, n-propoxy, i-propoxy, butoxy, iso-butoxy, sec-butoxy, and tert-butoxy); a “hydroxyalkyl” having a general formula of CₙH₂ₙOH where n is an integer, such as a linear or branched a C₁ to C₁₀ hydroxyalkyl, typically a linear or branched C₁ to C₄ hydroxyalkyl (e.g., hydroxymethyl, hydroxyethyl, hydroxypropyl, hydroxybutyl, hydroxypentyl, and hydroxyhexyl); an “alkoxycarbonyl group”, such as a linear or branched C₁ to C₆ carbonyl hydrocarbon (e.g., methoxycarbonyl, ethoxycarbonyl, propoxycarbonyl, isopropoxycarbonyl, butoxycarbonyl, pentoxycarbonyl, and hexyloxycarbonyl); a thiol group (SH); an “alkylthiol group” having a general formula of CₙH₂ₙSH where n is an integer, such as a linear or branched C₁ to C₆ alkylthiol group (e.g., thiolmethyl, thiolethyl, thiolpropyl, thiolbutyl, thiolpentyl, and thiolhexyl); a silyl group (SiR′₃) where each R′ is independently an H atom, an organic group such as an alkyl group or an aryl group; an amine group (NR′₂) where each R′is independently an H atom, an organic group such as an alkyl group or an aryl group, or a silyl group; a halide (X), such as fluoride (F), chloride (Cl), bromide (Br), and iodide (I); an “oxyhalide” (OX), such as oxyfluoride (OF), oxychloride (OCl), oxybromide (OBr), and oxyiodide (OI); a “haloalkyl group”, where one or more hydrogen atoms on an alkyl group or a cycloalkyl group is replaced with a halogen, such as a linear or branched C₁ to C₆ haloalkyl group having one or more halogen atoms (e.g., iodomethyl, bromomethyl, chloromethyl, fluoromethyl, trifluoromethyl, 2-chloroethyl, 2-fluoroethyl, 2,2,2-trifluoroethyl, and pentafluoroethyl); and a “haloaryl group”, where one or more hydrogen atoms on an aryl is replaced with a halogen, such as, for example a fluorobenzyl group. A substituent group may, in and of itself, be substituted. For example, a hydroxyalkyl group is a substituted alkyl group, where an H atom on the alkyl group is replaced with an OH group.

As used herein, the term “threshold voltage”, abbreviated as “Vt”, refers to a minimum gate voltage required to create a conductive path between the source and drain terminals of a field effect transistor (FET).

As used herein, the term “threshold voltage shifting layer” or “Vt shifting layer” refers to a layer which can be used in the gate stack of a field effect transistor, which can change the threshold voltage of that field effect transistor. When used herein, the term “threshold voltage shifting layer” may be equivalent to like terms such as “threshold voltage adjusting layer”, “work function adjusting layer”, “work function shifting layer”, “flatband voltage adjusting layer”, “flatband voltage shifting layer”, a “dipole layer”, or simply “layer”.

Articles “a” or “an” refer to a species or a genus including multiple species, depending on the context. As such, the terms “a/an”, “one or more”, and “at least one” can be used interchangeably herein.

The terms “comprising”, “including”, and “having” are open ended and do not exclude the presence of other elements or components, unless the context clearly indicates otherwise. Comprising, including, and having can be used interchangeably and include the meaning of “consisting of”. The phrase “consisting of”, however, indicates that no other features or components are present other than those mentioned, unless the context clearly indicates otherwise.

The term “about” as applied to a value generally refers to a range of numbers that is considered to be equivalent to the recited value (e.g., having the same function or result). In some instances, the term “about” may include numbers that are rounded to the nearest significant figure.

The term “essentially” as applied to a composition, a method, a system, or a structure generally means that the additional components do not substantially modify the properties and/or function of the composition, the method, the system, or the structure.

The term “substantially” as applied to a composition, a method, a system, or a structure generally refers to a proportion of a value, a property, a characteristic, or the like, or conversely a lack thereof, that is at least about 70%, at least about 80%, at least about 90%, at least about 95%, at least about 97%, at least about 98%, at least about 99%, at least about 99.5%, at least about 99.9%, or more, or any proportion between about 70% and about 100%. In some embodiments, the term “substantially” means a proportion of about 90%, about 95%, about 97%, about 98%, about 99%, about 99.5%, or about 99.9%.

The terms “on” or “over” may be used to describe a relative location relationship. For example, an element, a film, or a layer may be directly positioned on or over and physically contacting at least a portion another element, film, or layer; or, alternatively, an element, a film, or a layer may be on or over another element, film or layer but have one or more interposed elements, films, or layers therebetween. Therefore, unless the term “directly” is separately used, the terms “on” or “over” will be construed to be a relative concept. Similar to this, it will be understood that the terms “under”, “underlying”, or “below” describe a relative location relationship and should be construed to be relative concepts.

The terms “at least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B, and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Z₁).

It should be understood that every numerical range given throughout this disclosure is deemed to include the upper and the lower end points, and each and every narrower numerical range that falls within such broader numerical range, as if such narrower numerical ranges were all expressly written herein. By way of example, the phrase “from about 2 to about 4” or “from 2 to 4” includes 2 and 4 and the whole number and/or integer ranges from about 2 to about 3, from about 3 to about 4 and each possible range based on real (e.g., irrational and/or rational) numbers, such as from about 2.1 to about 3.9, from about 2.1 to about 3.4, and so on.

Unless stated otherwise, reference to a group of elements in the periodic table refers to elements within a given column on the periodic table. The group numbering is based on the International Union of Pure and Applied Chemistry (IUPAC) standards established in 1988 and in effect since. For example, the group 4 elements in the periodic table include titanium (Ti), zirconium (Zr), hafnium (Hf), and rutherfordium (Rf); the group 5 elements in the periodic table include vanadium (V), niobium (Nb), tantalum (Ta), and dubnium (Db); and the group 6 elements in the periodic table include chromium (Cr), molybdenum (Mo), tungsten (W), and seaborgium (Sg). The group 4, 5, and 6 elements are transition state metals. In another example, group 13 elements in the periodic table include boron (B), aluminum (Al), gallium (Ga), indium (In), thallium (TI), and nihonium (Nh). Notably, boron (B) is a metalloid; however, for the purposes of this disclosure, in some places through the disclosure, boron may be referred to as a metal and it is included with the other group 13 elements as a group 13 metal.

In certain places throughout the disclosure, a chemical compound, a functional group of a chemical compound, or a substituent or ligand may be referred to by a chemical name (e.g., an IUPAC name or a common name), a molecular formula which may be abbreviated, a structure which may omit hydrogen atoms for simplicity, or two or all of the proceeding. In cases where there is a conflict between the chemical name and the molecular formula and the structure, and the identity of the chemical compound, the functional group, or the substituent or ligand cannot be unambiguously ascertained by one of skill in the art, then the molecular formula shall prevail, followed by the structure, then the chemical name.

In this disclosure, any defined meanings do not necessarily exclude ordinary and customary meanings, in some embodiments.

### Description

Metal oxide semiconductor field effect transistors (MOSFETs) are a type of transistor with a source terminal, an insulted gate, and a drain terminal on a body. Application of a voltage to the gate alters the conductivity of a channel material between the source and the drain terminals, creating a conductive path that allows for a current (e.g., electrons for a n-type metal-oxide-semiconductor (NMOS) and holes for a p-type metal-oxide-semiconductor (PMOS)) to flow between the source and the drain. Thus, depending upon the voltage that is applied to the gate, an electrical signal can be switched on or off. The minimum gate voltage that is needed to create or terminate the conducting path between the source terminal and the drain terminal is referred to as the threshold voltage (Vt). Historically, MOSFETs have utilized an SiO₂ layer as a gate dielectric and a polysilicon layer as a gate electrode to form a gate stack. The continued scaling of MOSFETs, however, has required replacing SiO₂ with high-κ materials as the gate dielectric and polysilicon with metals as the gate electrode. The gate stack may further comprise other layers, such as a threshold voltage shifting layer for shifting the effective work function of the gate towards the Si conduction band in the case of NMOS or towards the Si valence band in the case of PMOS, allowing for independent control and/or shifting of the threshold voltage.

Multi-threshold complementary metal-oxide-semiconductor (CMOS) technology relies on transistors with multiple threshold voltages in order to optimize delay or power. Multi Vt shifting is essential for advanced CMOS devices, such as, for example, central processing unit (CPU) and system-on-a-chip (SoC). However, as scaling continues, the reduced dimensions of the gate cavity will only allow for thin layers of dielectric stack materials, including a threshold voltage shifting materials. Thus, methods for achieving very thin films of novel materials for threshold voltage shifting are of a high interest.

The present disclosure generally relates to thin films of a material that comprises one or more metals (M) and phosphorous (P) and to methods and systems for making said films and to semiconductor device structures comprising said films. In some embodiments, the metal and phosphorus containing film is a metal phosphide film. In some embodiments, the metal and phosphorus containing film is substantially free of oxygen and/or carbon. In some embodiments, the average thickness of the metal and phosphorus containing film is less than about 1 nm, and even less than about 0.1 nm. Such films may beneficially be used as a threshold voltage shifting layer in a gate stack of a field effect transistor (FET). In particular, in some embodiments, the disclosed metal and phosphorus containing films may be useful for decreasing the voltage at which a p-type MOSFET switches from an off-state to an on-state, while contributing only minimally to the equivalent oxide thickness (EOT) of the gate dielectric stack. In other embodiments, the disclosed metal and phosphorus containing films may be useful for increasing the voltage at which a n-type MOSFET switches from an off-state to an on-state. These and other advantages will be apparent from the disclosure of various aspects, embodiments, and configurations contained herein.

An aspect of the present disclosure is related to thin films or layers of a material that comprises one or more metals (M) and phosphorous (P). In various places throughout the disclosure, the films or layers comprising one or more metals and phosphorous may be referred to as a metal and phosphorus containing film. In some embodiments, the metal and phosphorus containing film comprises one or more metals and phosphorous; hence, the film may comprise other elements such as, for example, oxygen. In some embodiments, the metal and phosphorus containing film consists of or consists essentially of one or more metals and phosphorous. In some embodiments, the metal and phosphorus containing film does not comprise, or does not substantially comprise oxygen; hence, the metal and phosphorus containing film may be referred to as oxygen free. The lack of, or substantial lack of, or even a low oxygen content (e.g., an oxygen content of less than about 5.0% (atomic %), or less than about 1.0%, or less than about 0.1%) in the films may beneficially reduce the EOT of the film. In other embodiments, the metal and phosphorus containing film further comprises oxygen. In some embodiments, the metal and phosphorus containing film comprises, consists essentially of, or consists of one or more metals, phosphorous, and oxygen. Oxygen may be present in the film as an impurity, introduced during the deposition process (e.g., from one or more of the metal precursor(s), phosphorous precursor(s), and halogen reactant(s)) and/or it may be present as a result of oxygen migration into the film from neighboring layers; or, alternatively, oxygen may be intentionally introduced into the film during the deposition process. In either of these cases, the oxygen content of the film may be greater than about 5% (atomic %), or greater than about 10%, or greater than about 20%, or greater than about 30%, or greater than about 40%, or greater than about 50%. In some embodiments, the metal and phosphorus containing film does not comprise, or does not substantially comprise carbon; hence, the metal and phosphorus containing film may be referred to as carbon free. The lack of, or substantial lack of, or even a low carbon content (e.g., a carbon content of less than about 5.0% (atomic %), or less than about 1.0%, or less than about 0.1%) in the film may beneficially reduce the number of defects in the film resulting in improved performance. In some embodiments, the metal and phosphorus containing film does not comprise, or does not substantially comprise elemental phosphorous; hence, the metal and phosphorus containing film may be referred to as elemental phosphorous free. The lack of, or substantial lack of, or even a low elemental phosphorous content (e.g., an elemental phosphorous content of less than about 5.0% (atomic %), or less than about 1.0%, or less than about 0.1%) in the film may beneficially reduce the number of defects in the film resulting in improved performance. In some embodiments, the metal and phosphorus containing film comprises certain elements as impurities, such as, for example, one or more of hydrogen, carbon, nitrogen, oxygen, elemental phosphorous, and halogens. In some embodiments, the metal and phosphorus containing film may have a purity of at least about 90% (atomic %), or at least about 95%, or at least about 98%, or at least about 99%, or at least about 99.5%, or at least about 99.9%, or at least about 99.99%.

In some embodiments, the metal and phosphorus containing film comprises a metal phosphide. In some embodiments, the metal and phosphorus containing film consists of, or consists essentially of, a metal phosphide. A metal phosphide is a material that comprises M—P bond(s), where some, most, or all of the phosphorus has an oxidation state of −3. A metal phosphide may be represented by the general formula MPₓ, where the “x” is a variable ranging from about 0.1 to about 3, or more typically from about 0.5 to about 2, depending upon the oxidation state of the metal and the process conditions used to form the metal phosphide material. In some embodiments, the metal in the metal phosphide film is one or more of a transition state metal and a group 13 metal (including boron). For example, in some embodiments, the metal is one or more of a rare earth metal, a group 4 metal, a group 5 metal, a group 6 metal, and a group 13 metal. In various embodiments, the metal in the metal phosphide material may have an oxidation state of +2, or +3, or +4, or +5, or +6. Thus, in some embodiments, x is about ⅔, or about 1, or about 4/3, or about 5/3, or about 2. In other embodiments, the value of x may not be rational.

In some embodiments, the metal and phosphorus containing film further comprises oxygen. In some embodiments, the metal and phosphorus containing film comprises a metal oxyphosphide. In some embodiments, the metal and phosphorus containing film consists of, or consists essentially of, a metal oxyphosphide. A metal oxyphosphide is a material that comprises M—O bond(s) and M—P bond(s), where some, most, or all of the phosphorus has an oxidation state of-3. In some embodiments, the metal oxyphosphide comprises M—O bond(s) and M—P bond(s) but does not comprise, or does not substantially comprise, P—O bond(s). In some embodiments, the metal oxyphosphide comprises M—O bond(s), M—P bond(s), and P—O bond(s). In some embodiment, the metal oxyphosphide material is a mixture of a metal oxide material and a metal phosphide material. It may also be said that a metal oxyphosphide material is a metal phosphide material that further comprises oxygen. A metal oxyphosphide may be represented by the general formula MPₓO_{y}, where “x” is a variable ranging from about 0.1 to about 3, or more typically from about 0.5 to about 2, and “y” is a variable ranging from about 0.05 to about 3.5, more typically from about 0.1 to about 2, or more typically from about 0.2 to about 1 depending upon the oxidation state of the metal and the process conditions used to form the metal oxyphosphide material. In some embodiments, the metal in the metal oxyphosphide film is one or more of a transition state metal and a group 13 metal (including boron). For example, in some embodiments, the metal is one or more of a rare earth metal, a group 4 metal, a group 5 metal, a group 6 metal, and a group 13 metal. In some embodiments, x is about ½ and y is about ¼, or x is about ⅔ and y is about ½, or x is about 1 and y is about ½, or x is about ⅔ and y is about 1, or x is about 4/3 and y is about ½, or x is about 1 and y is about 1, or x is about ⅔ and y is about 3/2, or x is about 5/3 and y is about ½, or x is about 4/3 and y is about 1, or x is about ⅔ and y is about 2, or x is about 1 and y is about 3/2. Other combinations of x and y are possible. In some embodiments, the values of x and/or y may not be rational. In some embodiments, the oxidation state of the metal may vary across the thickness of the film and therefore the values of x and y may also vary across the thickness of the film.

In some embodiments, the metal and phosphorus containing film comprises a material having a general formula of MPₓ, where the “x” is a variable ranging from about 0.1 to about 3, or more typically from about 0.5 to about 2. In other embodiments, the metal and phosphorus containing film comprises a material having a general formula of MPₓO_{y}, where “x” is a variable ranging from about 0.1 to about 3, or more typically from about 0.5 to about 2, and “y” is a variable ranging from about 0.05 to about 3.5, more typically from about 0.1 to about 2, or more typically from about 0.2 to about 1. The metal (M) in the above general formulas (i.e., MPₓ and MPₓO_{y}) may be selected from a rare earth metal, a group 4 metal, a group 5 metal, a group 6 metal, a group 13 metal, and combinations thereof. In some embodiments, metal (M) in the above general formulas may be selected from scandium (Sc), yttrium (Y), lanthanum (La), cerium (Ce), lutetium (Lu), titanium (Ti), zirconium (Zr), hafnium (Hf), vanadium (V), niobium (Nb), tantalum (Ta), chromium (Cr), molybdenum (Mo), tungsten (W), boron (B), aluminum (Al), gallium (Ga), indium (In), and combinations thereof. In some embodiments, the metal and phosphorus containing film comprises a rare earth metal. For instance, the metal in the metal and phosphorus containing film may be selected from scandium (Sc), yttrium (Y), or a lanthanide. More specifically, the metal in the metal and phosphorus containing film may be selected from scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and combinations and mixtures thereof. In some embodiments, the metal in the metal and phosphorus containing film may be selected from scandium (Sc), yttrium (Y), lanthanum (La), cerium (Ce), and lutetium (Lu). In some embodiments, the metal and phosphorus containing film comprises a rare earth metal phosphide film. For example, the metal and phosphorus containing film may comprise, consist essentially of, or consist of one or more of scandium phosphide, yttrium phosphide, lanthanum phosphide, cerium phosphide, praseodymium phosphide, neodymium phosphide, promethium phosphide, samarium phosphide, europium phosphide, gadolinium phosphide, terbium phosphide, dysprosium phosphide, holmium phosphide, erbium phosphide, thulium phosphide, ytterbium phosphide, lutetium phosphide, and combinations and mixtures thereof. In other embodiments, the metal and phosphorus containing film comprises a rare earth metal oxyphosphide film. For example, the metal and phosphorus containing film may comprise, consist essentially of, or consist of one or more of scandium oxyphosphide, yttrium oxyphosphide, lanthanum oxyphosphide, cerium oxyphosphide, praseodymium oxyphosphide, neodymium oxyphosphide, promethium oxyphosphide, samarium oxyphosphide, europium oxyphosphide, gadolinium oxyphosphide, terbium oxyphosphide, dysprosium oxyphosphide, holmium oxyphosphide, erbium oxyphosphide, thulium oxyphosphide, ytterbium oxyphosphide, lutetium oxyphosphide, and combinations and mixtures thereof.

In some embodiments, the metal and phosphorus containing film comprises a group 4 element. For instance, the metal in the metal and phosphorus containing film may be selected from titanium (Ti), zirconium (Zr), hafnium (Hf), and combinations and mixtures thereof. In some embodiments, the metal and phosphorus containing film is comprises group 4 metal phosphide film. For example, the metal and phosphorus containing film may comprise, consist essentially of, or consist of one or more of titanium phosphide, zirconium phosphide, hafnium phosphide, and combinations and mixtures thereof. In other embodiments, the metal and phosphorus containing film comprises a group 4 metal oxyphosphide film. For example, the metal and phosphorus containing film may comprise, consist essentially of, or consist of one or more of titanium oxyphosphide, zirconium oxyphosphide, hafnium oxyphosphide, and combinations and mixtures thereof.

In some embodiments, the metal and phosphorus containing film comprises a group 5 element. For instance, the metal in the metal and phosphorus containing film may be selected from vanadium (V), niobium (Nb), tantalum (Ta), and combinations and mixtures thereof. In some embodiments, the metal and phosphorus containing film comprises a group 5 metal phosphide film. For example, metal and phosphorus containing film may comprise, consist essentially of, or consist of one or more of vanadium phosphide, niobium phosphide, tantalum phosphide, and combinations and mixtures thereof. In other embodiments, the metal and phosphorus containing film comprises a group 5 metal oxyphosphide film. For example, the metal and phosphorus containing film may comprise, consist essentially of, or consist of one or more of vanadium oxyphosphide, niobium oxyphosphide, tantalum oxyphosphide, and combinations and mixtures thereof.

In some embodiments, the metal and phosphorus containing film comprises a group 6 element. For instance, the metal in the metal and phosphorus containing film may be selected from chromium (Cr), molybdenum (Mo), tungsten (W), and combinations and mixtures thereof. In some embodiments, the metal and phosphorus containing film is a group 6 metal phosphide film. For example, the metal and phosphorus containing film may comprise, consist essentially of, or consist of one or more of chromium phosphide, molybdenum phosphide, tungsten phosphide, and combinations and mixtures thereof. In other embodiments, the metal and phosphorus containing film is a group 6 metal oxyphosphide film. For example, the metal and phosphorus containing film may comprise, consist essentially of, or consist of one or more of chromium oxyphosphide, molybdenum oxyphosphide, tungsten oxyphosphide, and combinations and mixtures thereof.

In some embodiments, the metal and phosphorus containing film comprises a group 13 element. For instance, the metal in the metal and phosphorus containing film may be selected from boron (B), aluminum (Al), gallium (Ga), indium (In), and combinations and mixtures thereof. In some embodiments, the metal and phosphorus containing film is a group 13 metal phosphide film. For example, the metal and phosphorus containing film may comprise, consist essentially of, or consist of one or more of boron phosphide, aluminum phosphide, gallium phosphide, indium phosphide, and combinations and mixtures thereof. In other embodiments, the metal and phosphorus containing film is a group 13 metal oxyphosphide film. For example, the metal and phosphorus containing film may comprise, consist essentially of, or consist of one or more of boron oxyphosphide, aluminum oxyphosphide, gallium oxyphosphide, indium oxyphosphide, and combinations and mixtures thereof.

The metal and phosphorus containing film may be position on or over at least a portion of a surface of a substrate, either directly on the substrate or on one or more other layers on the substrate, or it may be interposed between two or more other layers that are on the substrate. The substrate is not particularly limited and may be a semiconductor wafer or multiple semiconductor wafers. The substrate may comprise one or more material layers such as dielectric layers, insulating layers, metal layers, sacrificial layers, and so forth, in addition to the metal and phosphorus containing layer. The substrate may include various topological features, such as gaps, recesses, lines, trenches, vias, holes, or spaces between elevated portions formed within or on at least a portion of a layer of the substrate. The metal and phosphorus containing film may cover the entire surface of the substrate or only a portion of the surface of the substrate and may be present on the lateral surface(s) and/or the vertical surface(s) or sidewall(s) of various topological features if present. In some embodiments, the substrate is a silicon wafer. The silicon wafer may be a monocrystalline silicon wafer (e.g., a p-type monocrystalline silicon wafer). Alternatively, the silicon wafer may comprise silicon-germanium (SiGe). In some embodiments, the substrate further comprises a dielectric layer. The dielectric layer may essentially be one material layer, or it can comprise multiple thinner material layers of two or more materials. The dielectric layer may comprise silicon oxide. Additionally, or alternatively, the dielectric layer may comprise a high-κ material. In some embodiments, the substrate further comprises one or more of a metal layer and a capping layer. The different material layers may form a structure on the surface of the substrate. The structure can be or form part of a CMOS structure, such as one or more of a PMOS and NMOS structure, or other device structures.

The metal and phosphorus containing film may be a bulk material, and/or a uniform material layer, or it may be a non-uniform and even discontinuous thin material layer. The thickness of the metal and phosphorus containing film is not particularly limited. As used herein, the “thickness” may be an average thickness measured over a defined area of the film. Typically, the thickness of the metal and phosphorus containing film is between about 0.1 nm and about 100 nm, typically between about 0.1 nm and about 50 nm, or more typically between about 0.1 nm and about 10 nm. In certain embodiments, however, only a very thin layer of the metal and phosphorus containing material is desirable or allowable due to the dimensions of a semiconductor device structure. Thin layers of material may be desirable for many electronics applications, including affecting work function and/or threshold voltage adjustment in transistors, and such thin layers may possess different properties when compared to thicker or bulk material layers of the material. In these embodiments, the film may be continuous and uniform; or alternatively, the film may be discontinuous. In these embodiments, the average thickness of the metal and phosphorus containing film may be about 0.1 nm or more to about 2 nm or less, preferably about 0.1 nm or more to about 1 nm or less. In some embodiments, the thickness of the metal and phosphorus containing film is about 0.1, or about 0.2 nm, or about 0.3 nm, or about 0.4 nm, or about 0.5 nm, or about 0.6 nm, or about 0.7 nm, or about 0.8 nm, or about 0.9 nm, or about 1 nm, or about 1.1 nm, or about 1.2 nm, or about 1.3 nm, or about 1.4 nm, or about 1.5 nm, or about 1.6 nm, or about 1.7 nm, or about 1.8 nm, or about 1.9 nm, or about 2 nm, or any intermediate thickness between about 0.1 nm and about 2 nm or a narrower range of any two thickness within. In some embodiments, the thickness of the metal and phosphorus containing film is less than about 2 nm, or less than about 1.9 nm, or less than about 1.8 nm, or less than about 1.7 nm, or less than about 1.6 nm, or less than about 1.5 nm, or less than about 1.4 nm, or less than about 1.3 nm, or less than about 1.2 nm, or less than about 1.1 nm, or less than about 1 nm, or less than about 0.9 nm, or less than about 0.8 nm, or less than about 0.7 nm, or less than about 0.6 nm, or less than about 0.5 nm, or less than about 0.4 nm, or less than about 0.3 nm, or less than about 0.2 nm, or less than about 0.1 nm.

In some embodiments, the metal and phosphorus containing film is a threshold voltage shifting layer in a semiconductor device structure. For example, the metal and phosphorus containing film may be a threshold voltage shifting layer in a gate stack of a FET, such as a MOSFET. In these embodiments, the metal and phosphorus containing film may be disposed on or over a substrate comprising a dielectric layer, such as, for example a SiO₂ layer and/or a high-κ material layer. In these embodiments, the metal and phosphorus containing film may additionally or alternatively be disposed on or over a substrate comprising a interlayer or an interface layer. In these embodiments, the thickness of the metal and phosphorus containing film is typically less than 2 nm, or more typically less than 1 nm, or even less than 0.1 nm. Further, the metal and phosphorus containing film may have a low oxygen content or be oxygen free. Additionally, or alternatively, the metal and phosphorus containing film may have a low carbon content or be carbon free. Additionally, or alternatively, the metal and phosphorus containing film may be free of, or essentially free of, elemental phosphorous.

Another aspect of the present disclosure is related to methods of forming the metal and phosphorus containing films disclosed herein. The methods for forming the metal and phosphorus containing films may be used to form a structure comprising a threshold voltage shifting layer comprising a metal and phosphorus containing material. In some embodiments, metal and phosphorus containing films comprise a metal phosphide material or a metal oxyphosphide material. The methods comprise providing a substrate in a reaction space (i.e., one or more reaction chambers) and performing one or more deposition cycles of a cyclic deposition process comprising sequentially exposing at least a portion of a surface of the substrate to a metal precursor and to a phosphorous precursor, thereby forming a metal and phosphorous containing film on the at least a portion of the surface of the substrate. The cyclical deposition process can include one or more of an atomic layer deposition (ALD) process and a cyclical chemical vapor deposition (CVD) process.

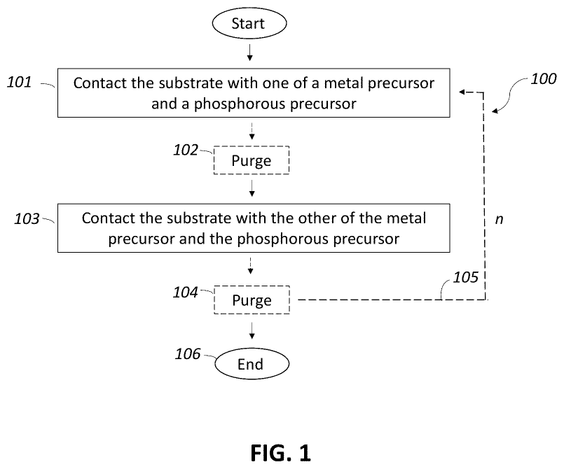

In some embodiments, the method for forming a metal and phosphorus containing film comprises providing a substrate in a reaction space and executing one or more deposition cycles of a cyclic deposition process 100, as shown in FIG. 1, comprising: exposing at least a portion of a surface of the substrate to one of a metal precursor and a phosphorous precursor 101; and exposing the at least a portion of the surface of the substrate to the other of the metal precursor and the phosphorus precursor 103, thereby forming a metal and phosphorous containing film on the at least a portion of the surface of the substrate. For example, at least a portion of a surface of the substrate may be exposed to a metal precursor, then to a phosphorus precursor. Additionally, or alternatively, at least a portion of a surface of the substrate may be exposed to a phosphorous precursor, then to a metal precursor. The cyclic deposition process may further comprise, purging the reaction space (102 and 104) between the exposing steps. Steps 101 and 103, with optional steps 102 and 104, make up one deposition cycle. The method may comprise repeating 105 the deposition cycle one or more (n) times in a cyclic deposition process to increase the uniformity and/or the thickness of the metal and phosphorous containing film on the at least a portion of the surface of the substrate. The cyclic deposition process may be terminated 106 once the desired uniformity and/or thickness of the metal and phosphorus containing film has been reacted.

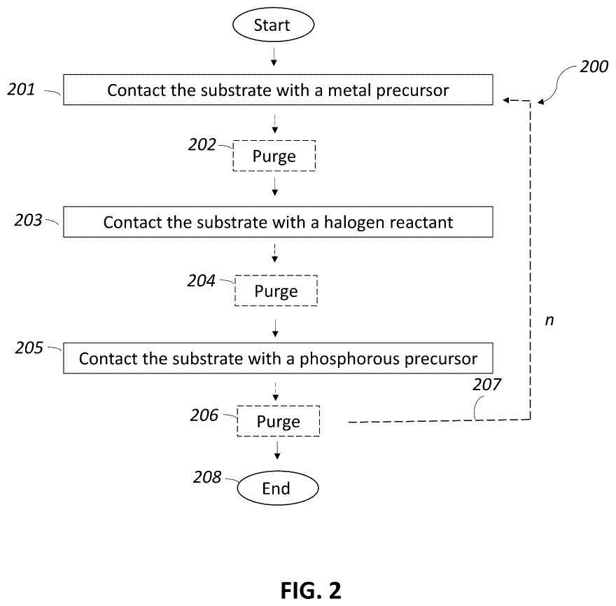

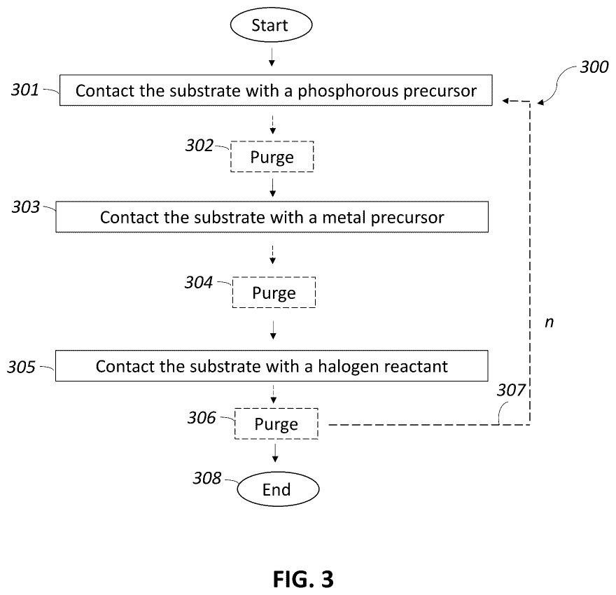

In certain embodiments, the method for forming a metal and phosphorus containing film further comprises, exposing the at least a portion of the surface of the substrate to a halogen reactant. The method may comprise, providing a substrate in a reaction space and executing one or more deposition cycles of a cyclic deposition process 200, as shown in FIG. 2, comprising: exposing at least a portion of a surface of the substrate to a metal precursor 201; exposing the at the least a portion of the surface of the substrate to a halogen reactant 203; and exposing the at least a portion of the surface of the substrate to a phosphorus precursor 205, thereby forming a metal and phosphorous containing film on the at least a portion of the surface of the substrate. Additionally, or alternatively, in some of these embodiments, the method for forming a metal and phosphorus containing film comprises, providing a substrate in a reaction space and executing one or more deposition cycles of a cyclic deposition process 300, as shown in FIG. 3, comprising: exposing at least a portion of a surface of the substrate to a phosphorus precursor 301; exposing the at least a portion of the surface of the substrate to a metal precursor 303; and exposing the at the least a portion of the surface of the substrate to a halogen reactant 305, thereby forming a metal and phosphorous containing film on the at least a portion of the surface of the substrate. In either of these embodiments, the deposition cycle may further comprise, purging the reaction space (202, 204, and 206 in FIGS. 2 and 302, 304, and 306 in FIG. 3) between the exposing steps. Steps 201, 203, and 205, with the optional purging steps 202, 204, and 206 make up one deposition cycle; similarly, steps 301, 303, and 305, with the optional purging steps 302, 304, and 306 make up one deposition cycle. In either of these embodiments, the method may further comprise repeating (207 in FIGS. 2 and 307 in FIG. 3) the deposition cycle one or more (n) time in a cyclic deposition process to increase the uniformity and/or the thickness of the metal and phosphorous containing film on the at least a portion of the surface of the substrate. The cyclic deposition process may be terminated once the desired uniformity and/or thickness of the metal and phosphorus containing film has been reacted (208 in FIGS. 2 and 308 in FIG. 3).

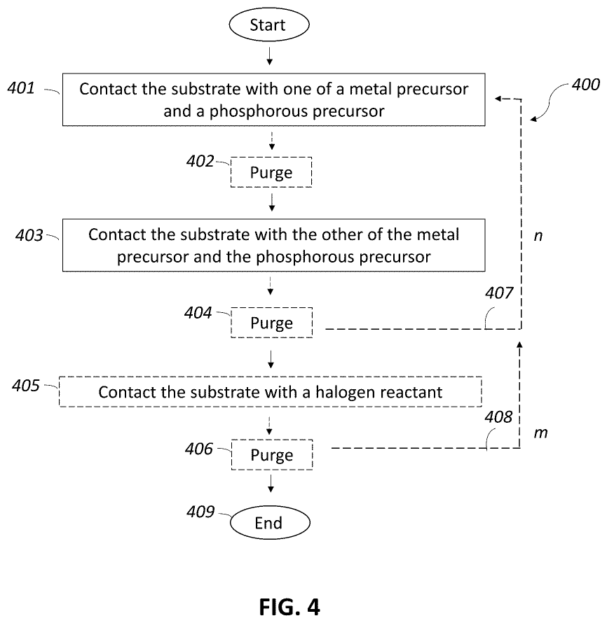

In some embodiments, where the method for forming a metal and phosphorus containing film further comprises exposing at least a portion of the surface of the substrate to a halogen reactant, the halogen reactant exposing step may occur, or may additionally occur, as a final step, after terminating the cyclic deposition process shown in any of FIG. 1, FIG. 2, and FIG. 3. Additionally, or alternatively, the step of exposing the at least a portion of the surface of the substrate to the halogen reactant may occur intermittently in the cyclic deposition process, or periodically in the cyclic deposition. For example, in some of these embodiments, the method comprises, providing a substrate in a reaction space and executing one or more deposition cycles of a cyclic deposition process 400, as shown in FIG. 4, comprising: exposing at least a portion of the surface of the substrate to one of a metal precursor and a phosphorus precursor 401; exposing the at least a portion of the surface of the substrate to the other of the metal precursor and the phosphorus precursor 403; and optionally exposing the at least a portion of the surface of the substrate to a halogen reactant 405, thereby forming a metal and phosphorous containing film on the at least a portion of the surface of the substrate. For example, at least a portion of a surface of the substrate may be exposed to a metal precursor, then to a phosphorus precursor, then optionally to a halogen reactant. Additionally, or alternatively, at least a portion of a surface of the substrate may be exposed to a phosphorous precursor, then to a metal precursor, then optionally to a halogen reactant. The cyclic deposition process may further comprise, purging the reaction space (402, 404, and 406) between the various exposing steps. The method may comprise repeating the exposing the at least a portion of the surface of the substrate to the metal precursor and to the phosphorus precursor one or more (n) time 407 and the exposing the at least a portion of the surface of the substrate to the halogen reactant at least once and one or more (m) time 408 to increase the uniformity and/or the thickness of the metal and phosphorous containing film on the at least a portion of the surface of the substrate. In some instances, the number of repeated halogen reactant exposing steps (m) may be equal to the number of repeated metal precursor and phosphorus precursor exposing steps (n) (i.e., m=n). (Note that, in some instance where m=n, the method is also described by the process diagram shown in FIG. 2. or FIG. 3.) In other instances, the number of repeated halogen reactant exposing steps (m) may be less than the number of repeated metal precursor exposing and phosphorus precursor exposing steps (n) (i.e., m<n); hence, only some of the deposition cycles comprises the step of exposing the at the least a portion of the surface of the substrate to the halogen reactant 405. For example, the at the least a portion of the surface of the substrate may be exposed to the halogen reactant every other deposition cycle, or every few deposition cycles, or only once as the final exposure step before terminating the process (i.e., m=0). The cyclic deposition process may be terminated 409 once the desired uniformity and/or thickness of the metal and phosphorus containing film has been reacted.

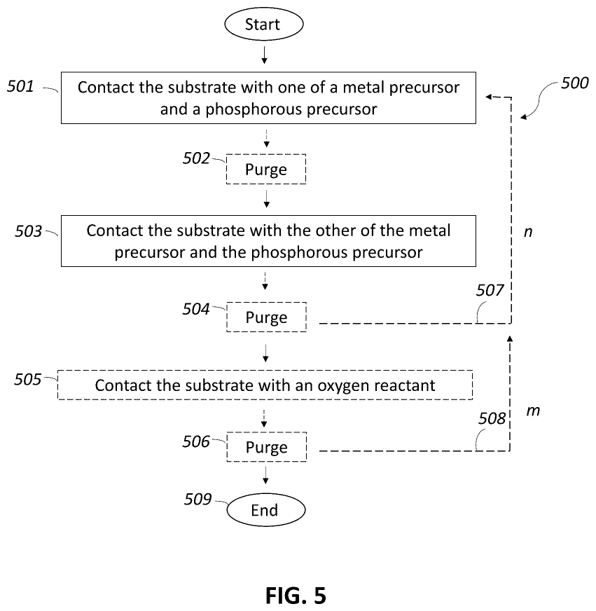

In certain embodiments, the method for forming a metal and phosphorus containing film further comprises exposing at least a portion of the surface of the substrate to an oxygen reactant. The step of exposing the at least a portion of the surface of the substrate to the oxygen reactant may occur as a final step, after terminating the cyclic deposition process shown in any of FIG. 1, FIG. 2, FIG. 3, and FIG. 4. Additionally, or alternatively, the step of exposing the at least a portion of the surface of the substrate to the oxygen reactant may occur intermittently in the cyclic deposition process, or periodically in the cyclic deposition. For example, in some of these embodiments, the method comprises, providing a substrate in a reaction space and executing one or more deposition cycles of a cyclic deposition process 500, as shown in FIG. 5, comprising: exposing at least a portion of a surface of the substrate to one of a metal precursor and a phosphorus precursor 501; exposing the at least a portion of the surface of the substrate to the other of the metal precursor and the phosphorus precursor 503; and optionally exposing the at least a portion of the surface of the substrate to an oxygen reactant 505, thereby forming a metal and phosphorous containing film further comprising oxygen on the at least a portion of the surface of the substrate. For example, at least a portion of a surface of the substrate may be exposed to a metal precursor, then to a phosphorus precursor, then optionally to an oxygen reactant. Additionally, or alternatively, at least a portion of a surface of the substrate may be exposed to a phosphorous precursor, then to a metal precursor, then optionally to an oxygen reactant. The cyclic deposition process may further comprise, purging the reaction space (502, 504, and 506) between the various exposing steps. The method may further comprise, repeating the exposing the at least a portion of the surface of the substrate to the metal precursor and the phosphorus precursor one or more (n) time 507 and the exposing the at least a portion of the surface of the substrate to the oxygen reactant at least once and then one or more (m) time 508 to increase the uniformity and/or the thickness of the metal and phosphorous containing film on the at least a portion of the surface of the substrate. In some instances, the number of repeated oxygen reactant exposing steps (m) may be equal to the number of repeated metal precursor and phosphorus precursor exposing steps (n) (i.e., m=n). In other instances, the number of repeated oxygen reactant exposing steps (m) may be less than the number of repeated metal precursor exposing and phosphorus precursor exposing steps (n) (i.e., m<n); hence, only some of the deposition cycles comprises the step of exposing at the least a portion of the surface of the substrate to the oxygen reactant 505. For example, the at the least a portion of the surface of the substrate may be exposed to the oxygen reactant every other deposition cycle, or every few deposition cycles, or only once as the final exposure step before terminating the process (i.e., m=0). The cyclic deposition process may be terminated 509 once the desired uniformity and/or thickness of the metal and phosphorus containing film has been reacted.

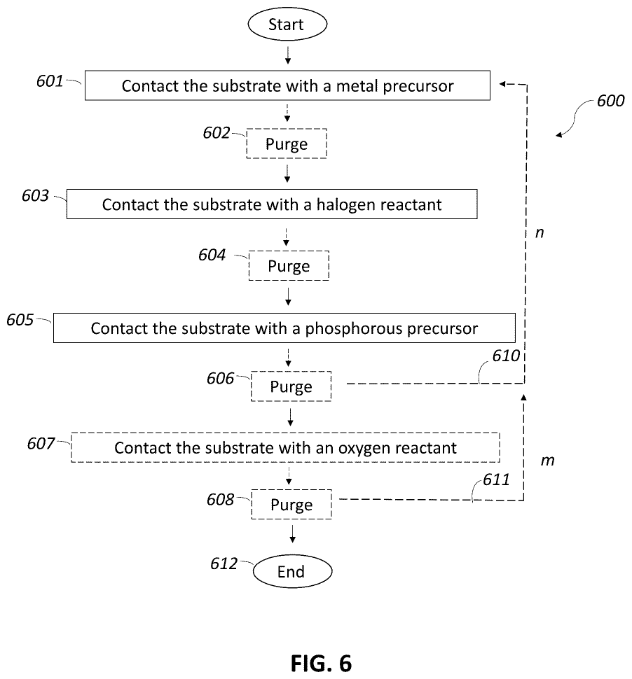

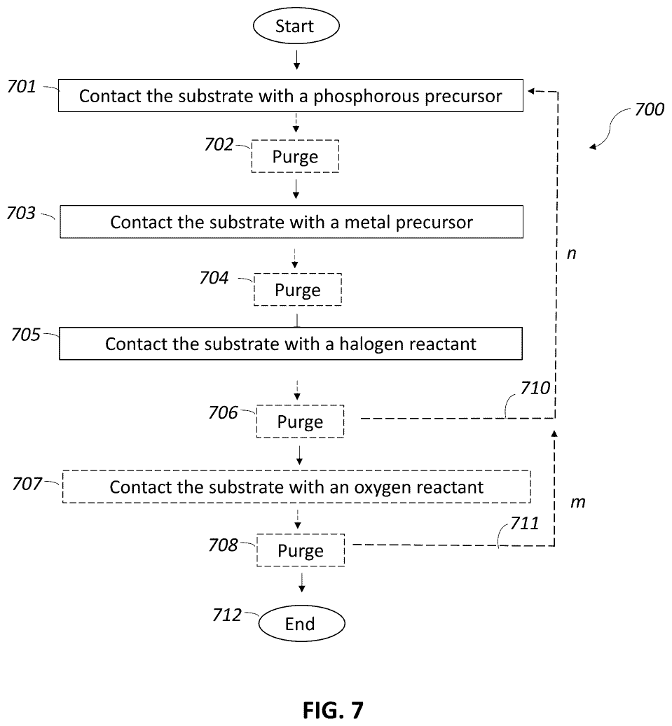

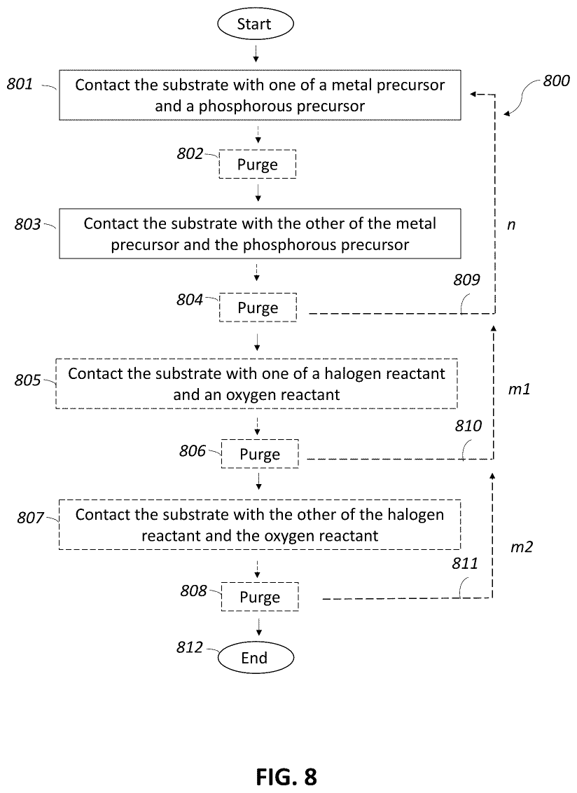

The process flow diagrams shown in FIG. 1, FIG. 2, FIG. 3, FIG, 4, and FIG. 5 and described above show exemplary embodiments of the methods for forming a metal and phosphorus containing film disclosed herein. However, it will readily be understood by those skilled in the art that certain process steps from one embodiment may be combined with certain other process steps from another embodiment, as appropriate, to obtain additional embodiments of the disclosed methods. For example, certain process steps from the embodiments shown in FIG. 2 and FIG. 5 may be combined to obtain the embodiment shown in FIG. 6. In another example, certain process steps from the embodiments shown in FIG. 3 and FIG. 5 may be combined to obtain the embodiment shown in FIG. 7. In yet another example, certain process steps from the embodiments shown in FIG. 4 and FIG. 5 may be combined to obtain the embodiment shown in FIG. 8. Further, it will readily be understood by those skilled in the art that other not shown process steps may be inserted in the cyclic deposition process, or before or after the cyclic deposition process, as appropriate. For instance, other reaction steps, activation steps, passivation steps, curing steps, and/or cleaning steps may be performed between the various steps or before or after the various steps. In another example, an annealing step may be performed periodically between the deposition cycles, or after the cyclic deposition process is complete.

In embodiments of the disclosure, a substrate is provided to a reaction space (i.e., one or more reaction chambers). The substrate is not particularly limited and is generally described above, along with certain specific and preferred embodiments. The reaction space is also not particularly limited and may comprise one or more reaction chambers of a semiconductor processing apparatus. In some embodiments, semiconductor processing apparatus is a cluster tool. In some embodiments, a reaction chamber or reaction chambers in a flow-type reactor may be utilized. In some embodiments, a reaction chamber or reaction chambers in a showerhead-type reactor may be utilized. In some embodiments, a reaction chamber or reaction chambers in a space divided reactor may be utilized. In some embodiments, a reaction chamber or reaction chambers in a high-volume manufacturing-capable single wafer reactor may be utilized. In other embodiments, a reaction chamber or reaction chambers in a batch reactor may be utilized. For embodiments in which a batch reactor is used, the reaction chamber may house a number of wafers, for example, the number of wafers may be in the range of 10 to 200, or 50 to 150, or even 100 to 150.

In some embodiments, the method further comprises purging the reaction space between the various exposing steps. For example, optional purging steps are shown in the process flow diagrams shown in 102 and 104 FIGS. 1; 202, 204, and 206 in FIGS. 2; 302, 304, and 306 in FIGS. 3; 402, 404, and 406 in FIGS. 4; 502, 504, and 506 in FIGS. 5; 602, 604, 606, and 608 in FIGS. 6; 702, 704, 706, and 708 FIGS. 7; and 802, 804, 806, and 808 in FIG. 8. As used herein, “purging” refers to clearing, removing, or replacing certain gas-phase and volatile species from a reaction space. Purging may be affected, for example, by evacuating the reaction space with a vacuum pump and/or by replacing the gas inside a reaction space with an inert or substantially inert gas such as argon or nitrogen. In some instances, a purging step may be implemented between two pulses of gases (e.g., reactants and/or precursors) which react with each other, or, in other instances, purging may be implemented between two pulses of gases that do not react with each other. Purging may avoid, or at least reduce, gas-phase interactions between two gases reacting with each other. Purging may be used to remove volatile or gas-phase reaction products from the surface of the substrate. It shall be understood that a purge can be affected either in time or in space, or both. For example, in the case of temporal purges, a purge step can be used in the temporal sequence of providing a first reactant to a reaction chamber, providing a purge gas to the reaction chamber, and then providing a second reactant to the reaction chamber, wherein the substrate on which a material is deposited does not move. For example, in the case of spatial purges, a purge step can involve moving a substrate from a first location to which a first reactant is continually supplied, through a purge gas curtain, to a second location to which a second reactant is continually supplied.

The various process steps may be repeated one or more times to grow a metal and phosphorus containing film having a target thickness and/or degree of uniformity on at least a portion of the surface of the substrate. As an example, referring to the embodiment shown in FIG. 1, the method may comprise repeating 107 steps 101 and 103 one or more (n) times, or repeating 107 steps 101, 102, 103, and 104 one or more (n) time, to form a metal and phosphorus containing film having a targeted thickness and/or degree of uniformity on the at least a portion of the surface of the substrate. In another example, referring to the embodiment shown in FIG. 2, the method may comprise repeating 207 steps 201, 203, and 205 one or more (n) times, or repeating 207 steps 201, 202, 203, 204, 205, and 206 one or more (n) time, to form a metal and phosphorus containing film having a targeted thickness and/or degree of uniformity on the at least a portion of the surface of the substrate. In another example, referring to the embodiment shown in FIG. 3, the method may comprise repeating 307 steps 301, 303, and 305 one or more (n) times, or repeating 307 steps 301, 302, 303, 304, 305, and 306 one or more (n) time, to form a metal and phosphorus containing film having a targeted thickness and/or degree of uniformity on the at least a portion of the surface of the substrate. In another example, referring to the embodiment shown in FIG. 4, the method may comprise repeating 407 steps 401 and 403 one or more (n) times, or repeating 407 steps 401, 402, 403, and 404 one or more (n) time, and optionally repeating 408 step 405 one or more (m) times, or steps 405 and 406 one or more (m) times, to form a metal and phosphorus containing film having a targeted thickness and/or degree of uniformity on the at least a portion of the surface of the substrate. In another example, referring to the embodiment shown in FIG. 5, the method may comprise repeating 507 steps 501 and 503 one or more (n) times, or repeating 507 steps 501, 502, 503, and 504 one or more (n) time, and optionally repeating 508 step 505 one or more (m) times, or steps 505 and 506 one or more (m) times, to form a metal and phosphorus containing film having a targeted thickness and/or degree of uniformity on the at least a portion of the surface of the substrate. In another example, referring to the embodiment shown in FIG. 6, the method may comprise repeating 610 steps 601, 603, 605 one or more (n) times, or repeating 610 steps 601, 602, 603, 604, 605 and 606 one or more (n) time, and optionally repeating 611 step 607 one or more (m) times, or steps 607 and 608 one or more (m) times, to form a metal and phosphorus containing film having a targeted thickness and/or degree of uniformity on the at least a portion of the surface of the substrate. In another example, referring to the embodiment shown in FIG. 7, the method may comprise repeating 710 steps 701, 703, 705 one or more (n) times, or repeating 710 steps 701, 702, 703, 704, and 705 one or more (n) time, and optionally repeating 711 step 707 one or more (m) times, or steps 707 and 708 one or more (m) times, to form a metal and phosphorus containing film having a targeted thickness and/or degree of uniformity on the at least a portion of the surface of the substrate. In another example, referring to the embodiment shown in FIG. 8, the method may comprise repeating 809 steps 801 and 803 one or more (n) times, or repeating 809 steps 801, 802, 803, and 804 one or more (n) time, and optionally repeating 810 step 805 one or more (m1) times, or steps 805 and 806 one or more (m1) times, and optionally repeating step 807 one or more (m2) times, or steps 807 and 808 one or more (m2) times, to form a metal and phosphorus containing film having a targeted thickness and/or degree of uniformity on the at least a portion of the surface of the substrate. In any of these embodiments, other pulse sequences are possible. For example, the substrate may be exposed to two or more pulses of the metal precursor, then exposed to the phosphorus precursor; or conversely, the substrate may be exposed to the two or more pulses of the phosphorus precursor, then exposed to the metal precursor.

The number of repeated cycles (n) is not particularly limited and depends on the growth per-cycle (GPC) rate of the metal and phosphorous containing material and the targeted thickness and/or degree of uniformity of the film. The GPC of the metal and phosphorus containing film may be less 3 Å/cycle, between about 0.01 and 3 Å/cycle, or between about 0.05 to about 2 Å /cycle, or between about 0.05 Å/cycle to 1 Å/cycle, or between about 0.05 Å/cycle to 0.5 Å/cycle). A lower GPC is beneficial as this can help facilitate obtaining the desired accuracy of film thickness and/or film uniformity. The number of repeated cycles (n) may be between 1 and about 1,000, typically between 1 and about 500,or between 1 and about 200, or between 1 and about 100, or between 1 and about 50, or between 1 and about 10. The halogen reactant and/or the oxygen reactant exposing step(s), if present, may optionally be repeated m times, periodically between the various n cycles (m<n) or prior to every cycle (m=n). The number of repeated halogen reactant and/or the oxygen reactant exposing step(s) (m) may be equal to or less than the number of repeated cycles (n), typically m is about n/2, about n/5, about n/10, or about n/25. In some embodiments, halogen reactant and/or the oxygen reactant exposing step(s) occur only once (m=0).

In accordance with some embodiments of the disclosure, the cyclic deposition process is a thermal deposition process. In these cases, the deposition process does not include use of a plasma to form activated species for use in the deposition process. For example, the cyclic deposition process may not comprise the use of plasma, may not comprise the formation or use of excited species, and/or may not comprise the formation or use of radicals in any of the process steps. In other embodiments, at least one process step in the cyclic deposition process uses a plasma to excite one or more precursors, one or more reactants, and/or one or more inert gases. In other words, a plasma is used to excite one or more precursors, one or more reactants, and/or one or more inert gases. For example, one or more of the metal precursor, the phosphorous precursor, the halogen reactant, the oxygen reactant, and an inert gas may be supplied through a plasma source to form excited or activated species. In some embodiments, one or more of the phosphorus precursor, the halogen reactant, and the oxygen reactant may be supplied through a plasma source to form excited or activated species. In some of these embodiments, one or more of the phosphorus precursor, the halogen reactant, and the oxygen reactant comprises a plasma species.

The method may further comprise, maintaining a temperature of the substrate at an elevated temperature (i.e., above room temperature). In some embodiments, the method further comprises heating the substrate to a temperature of at least about 40° C. to no more than about 500° C. In some embodiments, the method comprises maintaining the substrate temperature from at least about 40° C. to no more than about 500° C., typically from at least about 100° C. to no more than about 450° C., or from at least about 100° C. to no more than about 425° C., or from at least about 100° C. to no more than about 400° C., or from at least about 100° C. to no more than about 375° C., or from at least about 100° C. to no more than about 350° C., or from at least about 100° C. to no more than about 325° C., or from at least about 100° C. to no more than about 300° C., or from at least about 100° C. to no more than about 275° C., or from at least about 100° C. to no more than about 250° C., or from at least about 200° C. to no more than about 450° C., or from at least about 200° C. to no more than about 425° C., or from at least about 200° C. to no more than about 400° C., or from at least about 200° C. to no more than about 375° C., or from at least about 200° C. to no more than about 350° C. In some embodiments, the method is performed while maintaining the substrate at a temperature of less than about 450° C., or less than about 425° C., or less than about 400° C., or less than about 375° C., or less than about 350° C., or less than about 325° C., or less than about 300° C., or less than about 275° C., or less than about 250° C., or less than about 225° C., or less than about 200° C. In some embodiments, the method comprises maintaining the substrate temperature at about 50° C., or at about 75° C., or at about 100° C., or at about 125° C., or at about 150° C., or at about 175° C., or at about 200° C., or at about 225° C., or at about 250° C., or at about 275° C., or at about 300° C., or at about 325° C., or at about 350° C., or at about 375° C., or at about 400° C., or at about 425° C., or at about 450° C., or at about 475° C., or at about 500° C.

In certain embodiments, the method may further comprise annealing the substrate comprising the metal and phosphorous containing film. Typically, the annealing step is performed once the cyclic deposition method is complete. Annealing may be performed by heating the substrate comprising the metal and phosphorous containing film to an annealing temperature from at least about 300° C. to no more about 1,200° C. for a set period of time, typically from at least about 300° C. to no more than about 600° C. for low temperature annealing and from at least about 600° C. to no more than about 1,200° C., more typically from at least about 700° C. to no more than about 900° C., for high temperature annealing. Annealing may be performed in the same reaction chamber as where the cyclic deposition process occurs or in a separate reaction chamber from the where the cyclic deposition process occurs. Annealing may be performed in one or more of an inert environment (e.g., by flowing one or more of He, Ar, and N₂ into the chamber), an oxidizing environment (e.g., by flowing O₂ into the chamber), a reducing environment (e.g., by flowing H₂ into the chamber), and a nitriding environment (e.g., by flowing NH₃ into the chamber). The length of time of the anneal step may vary greatly, ranging from tens of seconds to hours. Further, more than one annealing step may be performed. An annealing step or multiple annealing steps may be performed to remove impurities in the film, for example to reduce the oxygen and/or carbon content of the film, and/or to alter the morphology of the film. Additionally, or alternatively, high temperature annealing may be performed as part of gate last manufacturing to drive all or part of the metal and phosphorous containing layer and/or other material layers on the substrate into one or more of an insulating layer, an interlayer, or a high-κ dielectric layer.

In addition to controlling the temperature of the substrate, the methods of the present disclosure may be performed in a reduced pressure environment. In some embodiments, the method further comprises controlling a pressure inside of the reaction space. The pressure within the reaction space may be between about 1 mTorr and about 760 Torr, or between about 0.5 Torr and about 30 Torr, such as about 10 Torr, or about 15 Torr, or about 20 Torr. In some embodiments, a pressure within the reaction space during the cyclic deposition process is less than about 500 Torr, or a pressure within the reaction chamber during the cyclic deposition process is between about 0.1 Torr and about 500 Torr, or between about 1 Torr and about 100 Torr, or between about 1 Torr and about 20 Torr. In some embodiments, a pressure within the reaction chamber during the cyclic deposition process is less than about 10 Torr, less than about 50 Torr, less than about 100 Torr, or less than about 300 Torr.

In the methods disclosed herein, at least a portion of the surface of the substrate is exposed to a phosphorus precursor. The phosphorus precursor is introduced into the reaction space and the at least a portion of the surface of the substrate is contacted with the phosphorus precursor. The phosphorus precursor may be in gaseous form, or it may be a liquid or a solid but it should have sufficient vapor pressure at or near room temperature such that it can be introduced into the reaction space and transported to the substrate surface. Additionally, or alternatively, the phosphorus precursor may be heated to provide sufficient vapor pressure (typically between 1-20 torr) and/or entrained in a flow of an inert carrier gas (e.g., nitrogen and/or a noble gas such as helium (He) and argon (Ar)) and introduced into the reaction space. In some embodiments, the substrate is exposed to the phosphorus precursor under thermal conditions. In other words, the phosphorus precursor is free of plasma species and the substrate is not exposed to plasma species (e.g., ionic species, radical species, atoms, metastable species, and/or excited species). In other embodiments, the phosphorus precursor is supplied through a plasma source to form plasma species. In some of these embodiments, the phosphorus precursor comprises a plasma species.

A number of suitable phosphorous precursors may be utilized in the methods disclosed herein. The phosphorous precursor comprises at least one phosphorous atom and one or more substituents. In some embodiments, the phosphorous precursor has a general structure of PR₃ (or PR¹R²R³) where each R is an independently selected substituent. For example, each substituent may independently be selected from a hydrogen atom; a halogen; an alkyl group; an aryl group; an alkyl halide group, an aryl halide group, an alkoxy group (i.e., OR′ where R′ is a substituent selected from a hydrogen atom, an alkyl group, and an aryl group); an amino group (i.e., NR′₂ where each R′ is a substituent independently selected from a hydrogen atom, an alkyl group, an aryl group, and a silyl group); a silyl group (i.e., SiR′₃ where each R′ is a substituent independently selected from a hydrogen atom, an alkyl group, an alkyl halide, an aryl group, an aryl halide, and a halide); and a siloxy group (i.e., OSiR′₃ where each R′ is a substituent independently selected from a hydrogen atom, an alkyl group, an alkyl halide, an aryl group, and an aryl halide). In some embodiments, the phosphorous precursor has a general structure of P(═O)R₃ (or P(═O)R¹R²R³) where each R is an independently selected substituent. For example, each substituent may independently be selected from a hydrogen atom; a halogen; an alkyl group; an aryl group; an alkyl halide group, an aryl halide group, an alkoxy group (i.e., OR′ where R′ is a substituent selected from a hydrogen atom, an alkyl group, and an aryl group); an amino group (i.e., NR′₂ where each R′ is a substituent independently selected from a hydrogen atom, an alkyl group, an aryl group, and a silyl group); a silyl group (i.e., SiR′₃ where each R′ is a substituent independently selected from a hydrogen atom, an alkyl group, an alkyl halide, an aryl group, and an aryl halide); and a siloxy group (i.e., OSiR′₃ where each R′ is a substituent independently selected from a hydrogen atom, an alkyl group, an alkyl halide, an aryl group, and an aryl halide).

In some embodiments, the phosphorous precursor is selected from the group consisting of: tetraphosphorus (P₄); phosphorus pentoxide (P₂O₅); phosphine (PH₃); an organophosphine (PH₃₋ₙRₙ where each R is a substituent independently selected from an alkyl group, a alkyl halide, an aryl group, and an aryl halide and n is 1, 2, or 3), such as, for example an alkyl phosphine or an aryl phosphine, more specifically, for example PR₃, PHR₂, and PH₂R, where R each is independently selected from a Me, Et, ⁿPr, ⁱPr, ⁿBu, ⁱBu, ^{s}Bu, ^{t}Bu, and Ph; an aminophosphine (PR₃₋ₙ(NR₃) n where each R is a substituent independently selected from a hydrogen atom, an alkyl group, and an aryl group and n is 1, 2, or 3), such as, for example PH₂(NR₂), PH(NR₂)₂, and P (N₂)₃, where R each is independently selected from a Me, Et, ⁿPr, ⁱPr, ⁿBu, ⁱBu, ^{s}Bu, ^{t}Bu, and Ph; a phosphoramide ((O)(NR₂)ₙ(OR)₃₋ₙ where each R is a substituent independently selected from a hydrogen atom, an alkyl group, and an aryl group and n is 1, 2, or 3) such as, for example P(O)(NR₂)₃, P(O)(NR₂)₂(OR), and P(O)(NR₂)(OR)₂ where R each is independently selected from H, Me, Et, ⁿPr, ⁱPr, ⁿBu, ⁱBu, ^{s}Bu, ^{t}Bu, and Ph; a silylphosphide (PR₃₋ₙ(SiR₃) n where each R is a substituent independently selected from a hydrogen atom, an alkyl group, an alkyl halide group, an aryl group, and an aryl halide group and n is 1, 2, or 3), such as, for example P(SiR₃)₃, PR(SiR₃)₂, PR₂(SiR₃) where R each is independently selected from H, Me, Et, ⁿPr, ⁱPr, ⁿBu, ⁱBu, ^{s}Bu, ^{t}Bu, and Ph; a silylphosphite (P(OSiR₃)ₙ(OR)₃₋ₙ where each R is a substituent independently selected from a hydrogen atom, an alkyl group, an alkyl halide group, an aryl group, and an aryl halide group and n is 1, 2, or 3) such as, for example P(OSiR₃)₃ where R each is independently selected from H, Me, Et, ⁿPr, ⁱPr, ⁿBu, ⁱBu, ^{s}Bu, ^{t}Bu, and Ph; a silylphosphate (P(O)(OSiR₃)(OR)₃₋ₙ where each R is a substituent independently selected from a hydrogen atom, an alkyl group, an alkyl halide group, an aryl group, and an aryl halide group and n is 1, 2, or 3) such as, for example P(O)(OSiR₃)₃ where R each is independently selected from H, Me, Et, ⁿPr, ⁱPr, ⁿBu, ⁱBu, ^{s}Bu, ^{t}Bu, and Ph; a phosphite ester (PHₙ₋₃(OR)ₙ or PRₙ₋₃(OR)ₙ where each R is a substituent independently selected from an alkyl group, an alkyl halide group, an aryl group, and an aryl halide group and n is 1, 2, or 3) such as, for example P(OR)₃ where R each is independently selected from Me, Et, ⁿPr, ⁱPr, ⁿBu, ⁱBu, ^{s}Bu, ^{t}Bu, and Ph; a phosphate ester (P(O)H₃₋ₙ(OR)ₙ or P(O)R₃₋ₙ(OR), where each R is a substituent independently selected from an alkyl group, an alkyl halide group, an aryl group, and an aryl halide group and n is 1, 2, or 3), such as, for example P(O)(OR)₃ where R each is independently selected from Me, Et, ⁿPr, ⁱPr, ⁿBu, ⁱBu, ^{s}Bu, ^{t}Bu, and Ph; a phosphorous halide (PX₃ or PX₅, where each X is independently selected from Cl, Br, and I); and a phosphoryl halide (POX₃ where each X is independently selected from Cl, Br, and I).

Suitable phosphorous precursors include, but are not limited to, phosphine (PH₃), tetraphosphorus (P₄), 1,2-diphosphinoethane (C₂H₈P₂), methyl phosphine (PH₂Me), trimethyl phosphine (PMe₃), ethyl phosphine (PH₂Et), triethyl phosphine (PEt₃), isopropylphosphine (PH₂ⁱPr), i-butylphosphine (PH₂ⁱBu), t-butylphosphine (PH₂^{t}Bu), dichloromethylphosphine (MePCl₂), dichloroethylphosphine (PCl₂Et), dichloropropylphosphine (PC₁₂ⁿPr), dichloroisopropylphosphine (PCl₂ⁱPr), dichlorobutylphosphine (PCl₂ⁿBu), dichlorotertbutylphosphine (PCl₂^{t}Bu), w(PClⁱPr₂), chloro(dimethyl)phosphine (PClMe₂), chloro(diethyl)phosphine (PClEt₂), chloro(di-secbutyl)phosphine (PCl^{s}Bu₂), bromo(di-secbutyl)phosphine (PBr^{t}Bu₂), chloro(di-tertbutyl)phosphine (PCl^{t}Bu₂), chloro(tertbutyl)(methyl)phosphine (PCl^{t}BuMe), cyclohexylphosphine (PH₂(C₆H₁₁), phenyl phosphine (PH₂Ph), 1,2-diphosphinobenzene, tris(1-pyrrolidinyl)phosphine (P(C₄H₈N)₃), dimethylaminophosphine (PH₂ (NMe₂)₂), bis(dimethylamino)phosphine (PH(NMe₂), dimethylamino(methyl)phosphine (PMe(NMe₂)₂), tris(dimethylamino)phosphine (P(NMe₂)₃), tris(diethylamino)phosphine (P(NEt₂)₃), chlorobis(dimethylamino)phosphine (PCl(NMe₂)₂), dichloro(dimethylamino)phosphine (PCl₂(NMe₂)), dichloro(diethylamino)phosphine (PCl₂(NEt₂)), chlorobis(diethylamino)phosphine (PCl(NEt₂)₂), chlorobis(diisopropylamino)phosphine (PCl(NiPr₂)₂), dichloro(diisopropylamino)phosphine (PCl₂(NiPr₂)), tris(dimethylamino)phosphine (P(NMe₂)₃), trisilylphosphine (P(SiH₃)₃), tris(trimethylsilyl)phosphine (P(SiMe₃)₃), tris(triethylsilyl)phosphine (P(SiEt₃)₃), tris(trimethylsiloxy)phosphine (P(OSiMe₃)₃), trimethyl phosphite (POMe₃), trimethyl phosphate (P(O)OMe₃), phosphorus pentoxide (P₂O₅), phosphorous trichloride (PCl₃), phosphorous tribromide (PBr₃), phosphorous triiodide (PI₃), phosphorous pentachloride (PCl₅), phosphorous pentabromide (PBr₅), phosphoryl chloride (POCl₃), and phosphoryl bromide (POBr₃).

In the methods disclosed herein, at least a portion of the surface of the substrate is exposed to a metal precursor. The metal precursor is introduced into the reaction space and at least a portion of the surface of the substrate is contacted with the metal precursor. The metal precursor may be in gaseous form, or it may be a liquid or a solid, but it should have sufficient vapor pressure at or near room temperature such that it can be introduced into the reaction space and transported to the substrate surface. Additionally, or alternatively, the metal precursor may be heated to provide sufficient vapor pressure (typically between 1-20 torr) and/or entrained in a flow of an inert carrier gas (e.g., nitrogen and/or a noble gas such as helium (He) and argon (Ar)) and introduced into the reaction space. In some embodiments, the substrate is exposed to the metal precursor under thermal conditions. In other words, the metal precursor is free of plasma species and the substrate is not exposed to plasma species (e.g., ionic species, radical species, atoms, metastable species, and/or excited species). In other embodiments, the metal precursor is supplied through a plasma source to form plasma species. In some of these embodiments, the metal precursor comprises a plasma species.

A number of suitable metal precursors may be utilized in the methods disclosed herein. In some embodiments, the metal in metal precursor is a transition state metal or a group 13 element. For example, in some embodiments, the metal is one or more of a rare earth element, a group 4 element, a group 5 element, a group 6 element, and a group 13 element. In some embodiments, the metal in the metal precursor is selected from the group consisting of scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), titanium (Ti), zirconium (Zr), hafnium (Hf), vanadium (V), niobium (Nb), tantalum (Ta), chromium (Cr), molybdenum (Mo), tungsten (W), boron (B), aluminum (Al), gallium (Ga), indium (In), and combinations and mixtures thereof. In some embodiments, the metal in the metal precursor is selected from the group consisting of scandium (Sc), yttrium (Y), lanthanum (La), cerium (Ce), lutetium (Lu), titanium (Ti), zirconium (Zr), hafnium (Hf), vanadium (V), niobium (Nb), tantalum (Ta), chromium (Cr), molybdenum (Mo), tungsten (W), boron (B), aluminum (Al), gallium (Ga), indium (In), and combinations and mixtures thereof.

In some embodiments, the metal precursor comprises a metal and one or more ligands coordinated around the metal (MLn). The number of ligands in the metal precursor depends upon the oxidation state of the metal, which may vary in different embodiments of the disclosure and may be +2, or +3, or +4, or +5, or +6. Suitable ligands include, but are not limited to, a halide, a carbonyl, an oxo, an alkyl, a cyclopentadienyl, an η⁶-arene, an alkoxide, an imido, an akyl amide, a silyl amide, a β-diketonate, an amidinate, a diazadiene, and a triazenide. In some embodiments, the metal precursor comprises one type of ligand (i.e., it is homoleptic), while in other embodiments, the metal precursor comprises two types of ligands, or three types of ligands, or more (i.e., it is heterolytic). In some embodiments, the metal precursor comprises one or more halide ligands (generically represented by “X”), such as fluoride (F), chloride (Cl), bromide (Br), or iodide (I) ligands. Coordination of halide ligand to the metal occurs through a M—X bond. In some embodiments, the metal precursor comprises one or more carbonyl ligands (CO). Coordination of a carbonyl ligand to the metal occurs through a M—C bond. In some embodiments, the metal precursor comprises one or more oxo ligands (O²⁻). Coordination of an oxo ligand can occur to one metal center as an M—O bond (generally a double or triple bond) or to two metal centers as M—O—M bonds. In some embodiments, the metal precursor comprises one or more alkyl ligands. An alkyl ligand may have a linear or branched structure with a general formula of CₙHₙ₊₁ where n is an integer that is typically between 1 and 10, more typically between 1 and 5. Coordination of an alkyl ligand to a metal occurs through a M—C bond. Example alkyl ligands include, but are not limited to, methyl (Me), ethyl (Et), n-propyl (ⁿPr), iso-propyl (ⁱPr), n-butyl (ⁿBu), sec-butyl (^{s}Bu), tert-butyl (^{t}Bu), neo-pentyl (ⁿPe), and tert-pentyl (^{t}Pe). In some embodiments, the metal precursor comprises one or more cyclopentadienyl ligands. A cyclopentadienyl ligand has a general formula of C₅R₅ where each R is an independently selected substituent, typically selected from a hydrogen, an alkyl, an alkyl halide, or a halogen. Coordination of a cyclopentadienyl ligand to the metal generally occurs through a pentahapto (η⁵) bonding mode. Example cyclopentadienyl ligands include, but are not limited to, cyclopentadienyl (Cp), methylcyclopentadienyl (MeCp), dimethylcyclopentadienyl (Me₂Cp), ethylcyclopentadienyl (EtCp), isopropylcyclopentadienyl (ⁱPrCp), isopropylcyclopentadienyl (ⁱPrCp), tert-butylcyclopentadienyl (^{t}BuCp), trimethylsilylcyclopentadienyl (TMSCp), pentamethylcyclopentadientyl (Cp*), 1,2,4-triisopropylcyclopentadienyl (ⁱPr₃Cp), and 1,2,4-tri-tert-butylcyclopentadienyl (^{t}Bu₃Cp). In some embodiments, the metal precursor comprises one or more η⁶-arene ligands. The simplest η⁶-arene ligands are benzene (C₆H₆) and substituted benzenes have a general formula of C₆R₆ where each R is an independently selected substituent, typically selected from a hydrogen, an alkyl group, an alkyl halide group, and a halogen. Coordination of an η⁶-arene ligand to the metal generally occurs through a hexahapto (η⁶) bonding mode. Example benzene ligands include, but are not limited to, benzene (Ben), methyl benzene (MeBen), and ethyl benzene (EtBen). In some embodiments, the metal precursor comprises one or more alkoxide ligands. An alkoxide ligand has a general formula of RO⁻ where R is a substituent, typically selected from an alkyl group, an alkyl halide an aryl group, an aryl halide, an alkenyl group, an alkynyl group, and an alkylsilyl group. Coordination of an alkoxide ligand to a metal occurs through a M—O bond. Example alkoxide ligands include, but are not limited to, methoxide (MeO), ethoxide (EtO), n-propoxide (ⁿPrO), isopropoxide (ⁱPrO), n-butoxide (ⁿBuO), sec-butoxide (^{s}BuO), tert-butoxide (^{t}BuO), 1-methoxy-2-methyl-2-propoxide (mmp), 1-dimethylamino-2-propoxide (dmap), 1-dimethylamino-2-methyl-2-propoxide (dmamp), and 1-dimethylamino-2-methyl-2-butoxide (dmamb), and phenoxide (PhO). In some embodiments, the metal precursor comprises one or more imido ligands. An imide ligand has a general formula of N-R, where R is a substituent, typically selected from an alkyl group, an alkyl halide group, an aryl group, an aryl halide group, an alkenyl group, an alkynyl group, and an alkylsilyl group. Coordination of an imido ligand to a metal occurs through a M═N bond. Example imide ligands include, but are not limited to, imido (NH), methylimido (NMe), ethylimido (NEt), isopropylimido (NⁱPr), tertbutylimido (N^{t}Bu), and phenylimido (NPh). In some embodiments, the metal precursor comprises one or more organoamindo ligands. An organoamido ligand has a general formula of NHR or NR₂ where each R is an independently selected substituent, typically selected from an alkyl group, an alkyl halide group, an aryl group, an aryl halide group, an alkenyl group, and an alkynyl group. Coordination of an organoamide ligand to a metal occurs through a M—N bond. Example organoamide ligands include, but are not limited to, methyl amido (NHMe), dimethyl amido (NMe₂), ethyl amido (NHEt), diethyl amido (NEt₂), ethyl methyl amido (NMeEt), iso-propyl amido (NH Pr), diisopropyl amido (NⁱPr₂), tert-butyl amido (NH^{t}Bu), and phenyl amido (NHPh). In some embodiments, the metal precursor comprises one or more silylamide ligands. An silylamide ligand has a general formula of NH (SiR₃) or N(SiR₃)₂ where each R is an independently selected substituent, typically selected from an alkyl group, an alkyl halide group, an aryl group, an aryl halide group, an alkenyl group, and an alkynyl group. Coordination of a silylamido ligand to a metal occurs through a M—N bond. Example silylamide ligands include but are not limited to bis (trimethylsilyl) amido (N(SiMe₃)₂, abbreviated as “hmds”). In some embodiments, the metal precursor comprises one or more β-diketonate ligands. A β-diketonate ligand has a general structure of RC(O)C(R)C(O)R where each R is an independently selected substituent, typically selected from a hydrogen, an alkyl group, an alkyl halide group, an aryl group, an aryl halide group, an alkenyl group, an alkynyl group, an alkylsilyl group, and a halogen. Additionally, or alternatively, two or more R groups may be connected to form one or more condensed ring structures. Coordination of a β-diketonate ligand to the metal typically occurs through two M—O bonds to form a six-membered chelate ring. Example B-diketonate ligands include, but are not limited to, acetylacetonate (CH₃C(O)CHC(O) CH₃, abbreviated as “acac”), hexafluoroacetylacetonate (CF₃C(O)CHC(O)CF₃, abbreviated as “hfac”), and 2,2,6,6-tetramethyl-3,5-heptanedionate ((CH₃)₃CC(O)CHC(O)C(CH₃)₃, abbreviated as “thd”). In some embodiments, the metal precursor comprises one or more amidinate ligands (abbreviated as AMD). An amidinate ligand has a general structure NRC(R)NR where each R is an independently selected substituent, typically selected from a hydrogen, an alkyl group, an alkyl halide group, an aryl group, an aryl halide group, an alkenyl group, an alkynyl group, an alkylsilyl group, and a halogen. Additionally, or alternatively, two or more R groups may be connected to form one or more condensed ring structures. Coordination of an amidinate ligand to a metal typically occurs through two M—N bonds to form a four-membered chelate ring. Example amidinate ligands include, but are not limited to N,N′-diisopropylformamidinate (CH₃CH(CH₃)NC(H)NCH(CH₃)CH₃, abbreviated as “ⁱPrFMD”), N,N′-di-tert-butylformamidinate (CH₃C(CH₃)₂NC(H)NC(CH₃)₂CH₃, abbreviated as “BuFMD”), N,N′-di-iso-propylacetamidinate (CH₃CH(CH₃)NC(CH₃)NCH(CH₃)CH₃, abbreviated as “ⁱPrAMD”), N,N′-di-tert-butylacetamidinate (CH₃C(CH₃)₂NC(CH₃)NC(CH₃)₂CH₃, abbreviated as “^{t}BuAMD”), and N,N′-di-sec-butylacetamidinate (CH₃CH₂CH(CH₃)NC(CH₃)NCH(CH₃)CH₂CH₃, abbreviated as “^{s}BuAMD”). In some embodiments, the metal precursor comprises one or more 1,4-diazadiene ligands (abbreviated as “DAD”). A 1,4-diazadiene ligand has a general structure of NRC(R)C(R)NR and may be in a neutral, anionic, or dianionic form, where each R is an independently selected substituent, typically selected from a hydrogen, an alkyl group, an alkyl halide group, an aryl group, an aryl halide group, an alkenyl group, an alkynyl group, a trialkylsilyl group, and a halogen. Additionally, or alternatively, two or more R groups may be connected to form one or more condensed ring structures, such as that of a bipyridine ligand (abbreviated as “bpy”) or terpyridine ligand (abbreviated as “tpy”). Coordination of a DAD ligand to the metal typically occurs through two M—N bonds to form a five-membered chelate ring. Example DAD ligands include, but are not limited to, 1,4-di-tert-butyl-1,4-diaza-1,3-butadiene (tBu2DAD), 1,4-diisopropyl-1,4-diaza-1,3-butadiene (ⁱPr₂DAD), 1,4-di-sec-butyl-1,4-diaza-1,3-butadiene (^{s}Bu2DAD), and 1,4-di-tert-pentyl-1,4-diaza-1,3-butadiene (ⁱPn₂DAD). In some embodiments, the metal precursor comprises one or more β-diketimine ligands (abbreviated as “NacNac”). A β-diketimine ligand has a general structure NRC(R)C(R)C(R)NR where each R is an independently selected substituent, typically selected from a hydrogen, an alkyl group, an alkyl halide group, an aryl group, an aryl halide group, an alkenyl group, an alkynyl group, a trialkylsilyl group, and a halogen. Additionally, or alternatively, two or more R groups may be connected to form one or more condensed ring structures. Coordination of a β-diketimine ligand to a metal typically occurs through two M—N bonds to form a six-membered chelate ring. In some embodiments, the metal precursor comprises one or more triazenide ligands. A triazenide ligand has a general structure RNNNR where each R is an independently selected substituent, typically selected from a hydrogen, an alkyl group, an alkyl halide group, an aryl group, an aryl halide group, an alkenyl group, an alkynyl group, a trialkylsilyl group, and a halogen. Coordination of a triazenide ligand to a metal typically occurs through two M—N bonds to form a four-membered chelate ring. An example triazenide ligand is 1,3-bisphenyltriazenide (PhNNNPh).

In some embodiments, the metal precursor comprises a rare earth metal. For instance, the metal in the metal precursor may be selected from scandium (Sc), yttrium (Y), or a lanthanide. More specifically, metal in the metal precursor may be selected from scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and combinations and mixtures thereof. Examples of metal precursors that comprise scandium, include, but are not limited to, tris(methylcyclopentadienyl) scandium (Sc(MeCp)₃), tris (isopropylcyclopentadienyl) scandium (Sc(ⁱPrCp)₃), bis (methylcyclopentadienyl)-3,5-dimethylpyrazolatescandium (Sc(MeCp)₂(Me₂pz)), bis(ethylcyclopentadienyl)-N,N′-diisopropylacetamidinatoscandium (Sc(EtCp)₂(ⁱPrAMD)), tris(N,N′-di-i-propylformamidinato) scandium (Sc(ⁱPrFMD)₃), tris(N,N′-di-i-propylacetamidinato)scandium (Sc(ⁱPrAMD)₃), and tris(2,2,6,6-tetramethyl-3,5-heptanedionato)scandium (Sc(thd)₃). Examples of metal precursors that comprise yttrium, include, but are not limited to, tris(methylcyclopentadienyl)yttrium (Y(MeCp)₃), tris(isopropylcyclopentadienyl)yttrium (Y(ⁱPrCp)₃), bis(ethylcyclopentadienyl)-N,N′-diisopropylacetamidinatoyttrium (Y(EtCp)₂(ⁱPrAMD)), tris(N,N′-diisopropyl-formamidinato)yttrium (Y(ⁱPr₂FMD)₃), tris(N,N′-diisopropylacetamidinato)yttrium (Y(ⁱPr₂AMD)₃), tris(N,N′-diisopropyl-2-dimethylamidoguanidinato)yttrium (Y(dpguan)₃), and tris(2,2,6,6-tetramethyl-3,5-heptanedionato)yttrium (Y(thd)₃). Examples of metal precursors that comprise lanthanum, include, but are not limited to, tris(methylcyclopentadienyl)lanthanum (La(MeCp)₃), tris(isopropylcyclopentadienyl)lanthanum (La(ⁱPrCp)₃), bis(ethylcyclopentadienyl)-N,N′-diisopropylacetamidinatolanthanum (La(EtCp)₂(ⁱPrAMD)), lanthanum formamidinate (La(FMD)₃), tris(N,N′-diisopropylformamidinato)lanthanum (La(ⁱPrFMD)₃), tris(N,N′-diisopropylacetamidinato)lanthanum (La(PrAMD)₃), tris(2,2,6,6-tetramethyl-3,5-heptanedionato) (La(thd)₃), tris(2,2,6,6-tetramethyl-3,5-heptanedione) (N,N′-dimethylethylenediamido) lanthanum lanthanum (La(thd)₃(dmea)), and tris(bis(trimethylsilyl)amido)lanthanum (La(N(SiMe₃))₂. Examples of metal precursors that comprise cerium, include, but not are limited to, tris(methylcyclopentadienyl)cerium(Ce(MeCp)₃), tris(isopropylcyclopentadienyl)cerium (Ce(ⁱPrCp)₃), bis(isopropylcyclopentadienyl)-N,N′-diisopropylacetamidinatocerium (Ce(ⁱPrCp)₂(ⁱPrAMD)), cerium acetylacetonate (Ce(acac)₄), tetrakis(1,1,1,5,5,5-hexafluoropentanedionato)cerium (Ce(hfac)₄), tetrakis(2,2,6,6-tetramethyl-3,5-heptanedionato)cerium (Ce(thd)₄), tris(2,2,6,6-tetramethyl-3,5-heptanedionate)-1,10-phenanthrolinecerium (Ce(thd)₃ (phen)), tris(N,N′-diisopropylformamidinato) cerium (Ce(ⁱPrFMD)₃), tris(N,N′-diisopropylacetamidinate)cerium (Ce(ⁱPr₂AMD)₃), tetrakis(1-(methoxy)-2-methyl-2-propanolato)cerium (Ce(mmp)₄), tris(N,N′-diisopropyl-2-dimethylamidoguanidinato)cerium (Ce(dpguan)₃), and tris(bis (trimethylsilylamido))cerium Ce(N(SiMe₃)₂)₃. Other metal precursors comprising a rare earth metal are known in the art. One of skill in the art will recognize other rare earth metal ligand combinations that are suitable for the methods disclosed herein.

In some embodiments, the metal precursor comprises a group 4 element. For instance, the metal in the metal precursor may be selected from titanium (Ti), zirconium (Zr), hafnium (Hf), and combinations and mixtures thereof. Examples of metal precursors that comprise titanium, include, but are not limited to, titanium tetrafluoride (TiF₄), titanium tetrachloride (TiCl₄), titanium tetrabromide (TiBr₄), titanium tetraiodide (TiI₄), titanium tetramethoxide (Ti(OMe)₄), titanium tetraethoxide (Ti(OEt)₄), titanium tetraisopropoxide (Ti(OⁱPr)₄), tetrakis(dimethylamido)titanium (Ti(NMe₂)₄), tetrakis(diethylamido)titanium (Ti(NEt₂)₄), and tris(dimethylamido)methylcyclopentadienyl titanium (Ti(MeCp)(NMe₂)₃). Examples of metal precursors that comprise zirconium, include, but are not limited to, zirconium tetrachloride (ZrCl₄), zirconium tetrabromide (ZrBr₄), zirconium tetramethoxide (Zr(OMe)₄), zirconium tetraethoxide (Zr(OEt)₄), zirconium tetratertbutyl (Zr(O^{t}Bu)₄), tetrakis(dimethylamido)zirconium (Zr(NMe₂)₄), tetrakis (ethylmethylamido) zirconium (Zr(N(Me)(Et))₄), dicyclopentadienyl zirconium dichloride (ZrCl₂Cp₂), (dicyclopentadienyl)(dimethyl)zirconium (ZrMe₂Cp₂), cyclopentadienyltris(dimethylamino)zirconium (ZrCp(NMe₂)₃), and tris(N,N′-diisopropylacetamidinato)zirconium (Zr(ⁱPr₂AMD)₃). Examples of metal precursors that comprise hafnium, include, but are not limited to, hafnium tetrachloride (HfCl₄), hafnium tetrabromide (HfBr₄), tetrakis(1-methoxy-2-methyl-2-propoxy)hafnium (Hf(OC(CH₃)₂CH₂OCH₃)₄), tetra (tert-butoxy) hafnium (Hf(O^{t}Bu)₄), tetrakis(dimethylamido)hafnium (Hf(NMe₂)₄), tetrakis(diethylamido)hafnium (Hf(NEt₂)₄), tetrakis(ethylmethylamido)hafnium (Hf(N(Me)(Et))₄), tetra(1-methoxy-2-methyl-2-propoxy)hafnium (Hf(mmp)₄), and tris(dimethylamido) cyclopentadienylhafnium (HfCp(NMe₂)₃). Other metal precursors comprising titanium, zirconium, and/or hafnium are known in the art. One of skill in the art will recognize other group 4 metal ligand combinations that are suitable for the methods disclosed herein.

In some embodiments, the metal precursor comprises a group 5 element. For instance, the metal in the metal precursor may be selected from vanadium (V), niobium (Nb), tantalum (Ta), and combinations and mixtures thereof. Examples of metal precursors that comprise vanadium, include, but are not limited to, vanadium pentafluoride (VF₅), vanadium pentabromide (VBr₅), vanadium tetrachloride (VCl₄), vanadium oxide trichloride (VOCl₃), tris(isopropoxy) oxovanadium (VO(OⁱPr)₃, tetrakis(ethylmethylamido)vanadium (V(NEtMe)₄), tris(N,N′-diethylacetamidinato)vanadium (V(Et₂AMD)₃), tris(N,N′-diisopropylacetamidinato) vanadium (V(Pr₂AMD)₃), and vanadium acetylacetonate (V(acac)₃). Examples of metal precursors that comprise niobium, include, but are not limited to, niobium pentafluoride (NbF₅), niobium pentachloride (NbCl₅), niobium pentaiodide (NbI5), niobium pentabromide (NbBr5), niobium pentaethoxide (Nb(OEt)₅), tetrakis(2,2,6,6,-tetramethylheptane-3,5-dionato) iobium (Nb (thd)₄), pentakis(dimethylamido)niobium (Nb(NMe₂)₅), pentakis(diethylamido)niobium (Nb(NEt₂)₅), tris(diethylamido)(tert-butylimido)niobium (Nb(N^{t}Bu)(NEt₂)₃), tris(dimethylamido) (tert-butylimido)niobium (Nb(N^{t}Bu)(NMe₂)₃), tris(ethylmethylamido)(tert-butylimido)niobium (Nb(N^{t}Bu)(NEtMe)₃), and (tert-amylimido)tris(tert-butoxy)niobium (Nb(N^{t}Amyl)(O^{t}Bu)₃). Examples of metal precursors that comprise tantalum, include, but are not limited to, tantalum pentachloride (TaCl₅), tantalum pentabromide (TaBr₅), tantalum pentaiodide (TaI₅), pentakis(dimethylamido)tantalum (Ta(NMe₂)₅), tantalum pentaethoxide (Ta(OEt)₅), pentakis(diethylamido)tantalum (Ta(NEt₂)₅), tris(diethylamido)(tert-butylimido)tantalum (Ta(N^{t}Bu)(NEt₂)₃), tris(dimethylamido)(tert-butylimido)tantalum (Ta(NtBu)(NMe₂)₃), tris(ethylmethylamido)(tert-butylimido)tantalum (Ta(N^{t}Bu)(NEtMe)₃), tris(dimethylamido)(tert-amylimido)tantalum (Ta(NtAmyl)(NMe₂)₃), bis(diethylamido)cyclopentadienyl (tert-butylimido)tantalum (TaCp(N^{t}Bu)(NEt₂)₂) (dimethylamido) bis(N,N′-isopropylacetamidinato)(tert-butylimido)tantalum (Ta(N^{t}Bu)(ⁱPrAMD)₂(NMe₂)), (tert-butylimido)tris(3,5-di-tert-butylpyrazolate)tantalum, (Ta(N^{t}Bu)(^{t}Bu₂pz)₃), (isopropylimido) tris(tert-butoxy)tantalum (Ta(NiPr)(O^{t}Bu)₃), and (tert-butylimido) tris(tert-butoxy)tantalum (Ta(N^{t}Bu)(O^{t}Bu)₃). Other metal precursors comprising vanadium, niobium, or tantalum are known in the art. One of skill in the art will recognize other group 5 metal ligand combinations that are suitable for the methods disclosed herein.

In some embodiments, the metal precursor comprises a group 6 element. For instance, the metal in the metal precursor may be selected from chromium (Cr), molybdenum (Mo), tungsten (W), and combinations and mixtures thereof. Examples of metal precursors that comprise chromium, include, but are not limited to, tris(2,2,6,6-tetramethyl-3,5-heptanedionato)chromium (Cr(thd)₃), chromyl chloride (CrO₂Cl₂), bis(cyclopentadienyl)chromium (CrCp₂), bis(ethylbenzene) chromium (CrEtBz), chromium acetylacetonate (Cr(acac)₃), and chromium hexacarbonyl (Cr(CO)₆). Examples of metal precursors that comprise molybdenum, include, but are not limited to, molypentachloride (MoCl₅), dichlorodioxomolybdenum (MoO₂Cl₂), tetrakis(dimethylamide)molybdenum (Mo(NMe₂)₄), tetrakis(diethylamide)molybdenum (Mo(NEt₂)₄), bis(tert-butylimido)bis(tert-butoxy)molybdenum (Mo(tBuN)₂(NMe₂)₂), bis(tert-butylimido)bis(ethoxy)molybdenum (Mo)(^{t}BuN)₂(NEt₂)₂), 2,2,6,6-tetramethylheptane-3,5-dionatomolybdenum (Mo(thd)₃), molybdenum acetylacetonate Mo(acac)₃, molybdenum hexacarbonyl (Mo(CO)₆), biscyclopentadienyldihydridomolybdenum Mo(Cp)₂H₂, bis(isopropyl)cyclopentadienyldihydridomolybdenum (Mo(ⁱPrCp)₂H₂), bis(N,N′-isopropylacetamidinato)(tert-butylimido)molybdenum (Mo(N^{t}Bu)₂(ⁱPrAMD)₂), and bis(ethylbenzene) molybdenum (Mo(η⁶-EtBz)₂. Examples of metal precursors that comprise tungsten, include, but are not limited to, tungsten pentachloride (WCl₅), tungsten hexafluoride (WF₆), tungsten hexacarbonyl bis(tert-butylimido)bis(dimethylamido)tungsten (W(N^{t}Bu)₂(NMe₂)), bis(N,N′-(W(CO)₆), isopropylacetamidinato)(tert-butylimido)tungsten (W(N^{t}Bu)₂)₂(ⁱPrAMD)₂), and bis(isopropyl)cyclopentadienyldihydridotungsten (W(ⁱPrCp)₂H₂). Other metal precursors comprising chromium, molybdenum, or tungsten are known in the art. One of skill in the art will recognize other group 6 metal ligand combinations that are suitable for the methods disclosed herein.

In other embodiments, the metal precursor comprises a group 13 element. For instance, the metal in the metal precursor may be selected from boron (B), aluminum (Al), gallium (Ga), indium (In), and combinations and mixtures thereof. Examples of metal precursors that comprise boron, include, but are not limited to, trimethylborate (B(OMe)₃), trimethylborane (BMe₃), triethylborane (BEt₃), tris(dimethylamino)borane (B(NMe₂)₃), boron tribromide (BBr₃), boron trichloride (BCl₃), boron triiodide (BI₃), borazine (B₃H₄N₃), and trichloroborazine (B₃Cl₃H₃N₃). Examples of metal precursors that comprise aluminum, include, but are not limited to, aluminum trichloride (AlCl₃), aluminum tribromide (AlBr₃), aluminum triiodide (AlI₃), trimethyl aluminum (AlMe₃), triethyl aluminum (AlEt₃), bis(tertbutyl)methylaluminium (^{t}Bu₂AlMe), triisobutylaluminium (Al(ⁱBu)₃), trineopentylaluminium (Al(ⁿPe)₃), dimethylaluminum hydride (AlHMe₂), aluminum methoxide (Al(OMe)₃), aluminum ethoxide (Al(OEt)₃), aluminum isopropoxide (Al(OiPr)₃), dimethylaluminum iso-propoxidealuminum (AlMe₂OⁱPr), dimethylaluminum chloride (AlMe₂Cl), tris(dimethylamino)aluminum Al(NMe₂)₃, tris(diethylamino)aluminum (Al(NEt₂)₃), diethyl-(N,N′-diisopropylamidinato)aluminum (Al(ⁱPrAMD)Et₂), 3-(dimethylamino)propylaluminium (Al(DMP)₃), tris(1-dimethylamino-2-methyl-2-propoxy)aluminum (Al(dmamp)₃), tri(1-methoxy-2-methyl-2-propoxy)aluminum (Al(mmp)₃), dimethyl-3-(dimethylamino) propylaluminum (AlMe₂(DMP)), bis-(diisopropylamido)(3-dimethylamino)propylaluminum (Al(NⁱPr₂)(DMP)), tris(N,N′-diisopropyl-2-dimethylamidoguanidinato)aluminum (Al(dpguan)₃), tris(neopentyl)aluminum (Al(ⁿPe)₃), and aluminum acetylacetonate (Al(acac)₃). Examples of metal precursors that comprise gallium, include, but are not limited to, gallium trichloride (GaCl₃), gallium tribromide (GaBr₃), gallium triiodide (Gal₃), trimethylgallium (GaMe₃), triethylgallium (GaEt)₃, trineopentylgallium (Ga(ⁿPe)₃), gallium acetylacetonate (Ga(acac)₃), tris-2,2,6,6-tetramethyl-heptane-3,5-dione gallium (Ga(thd)₃), tris(1-dimethylamino-2-methyl-2-propoxy)gallium (Ga(dmamp)₃), tris(1,3-diisopropyltriazenide)gallium (Ga(triaz)₃), dimethylethylgallium (GaEtMe₂), tris(N,N′-diisopropylamidinato)gallium (Ga(PrAMD)₃), tris(N,N′-diisopropylformamidinato)gallium (Ga(ⁱPrFMD)₃), and diethyl-bis(trimethylsilyl)amino gallium (Ga(N(SiMe₃)₂)Et₂). Examples of metal precursors that comprise indium, include, but are not limited to, trimethylindium (InMe₃), triethylindium (InEt₃), dimethylethylindium (InEtMe₂). trineopentylindium (In(ⁿPe)₃), dimethylindium chloride (InClMe₂), indium trichloride (InCl₃), indium tribromide (InBr₃), indium triiodide (InI₃), indium acetylacetonate (In(acac)₃), tris(dimethylamino-2-methyl-2-propoxy)indium (In(dmamp)₃, (isopropoxide)bis(dimethylamino-2-methyl-2-propoxy)indium (In(dmamp)₂(OⁱPr)), ethylcyclopentadienylindium (In(EtCp)), 1-methylbutylcyclopentadienylindium (In(Cp(Me)(Bu))), tris(N,N′-diisopropylformamidinato)indium (In(ⁱPrFMD)₃, tris(N,N′-diisopropylamidinato)indium (In(ⁱrAMD)₃), diethyl[bis(trimethylsilyl)amido]indium (In(N(SiMe₃)₂)Et₂), tris-2,2,6,6-tetramethyl-heptane-3,5-dione indium (In(thd)₃), tris(1,3-diisopropyltriazenide)indium (In(triaz)₃), dimethyl(N-ethoxy-2,2-dimethylpropanamido)indium (InMe₂(edpa)), dimethyl-(N-(tert-butyl)-2-methoxy-2-methylpropan-1-amine)indium (InMe₂(N^{t}Bu(CH₂)(CH₃)₂OMe), trimethyl-(N-(tert-butyl)-2-methoxy-2-methylpropan-1-amine)indium (InMe₂(N^{t}Bu(CH₂)(CH₃)₂OMe), and tris(N,N′-diisopropyl-2-dimethylamidoguanidinato)indium (In(dpguan)₃). Other metal precursors comprising boron, aluminum gallium, or indium are known in the art. One of skill in the art will recognize other group 13 element ligand combinations that are suitable for the methods disclosed herein.

In certain embodiments of the methods disclosed herein, the substrate is exposed to a halogen reactant. The halogen reactant is introduced into the reaction space and at least a portion of the surface of the substrate is contacted with the halogen reactant. The halogen reactant may be in gaseous form, or it may be a liquid or a solid but it should have sufficient vapor pressure (typically between 1-20 torr) at or near room temperature such that it can be introduced into the reaction space and transported to the substrate surface. Additionally, or alternatively, the halogen reactant may be heated to provide sufficient vapor pressure and/or entrained in a flow of an inert carrier gas (e.g., nitrogen and/or a noble gas such as helium (He) and argon (Ar)) and introduced into the reaction space.

In some embodiments, the halogen reactant comprises one or more bonds selected from a C—X bond, a P—X bond, a N—X bond, and a S—X bond, where X is a halogen atom selected from the group consisting of F, Cl, Br, and I. Suitable halogen reactants include, but are not limited to, carbon tetrafluoride (CF₄), carbon tetrachloride (CCl₄), carbon tetrabromide (CBr₄), bis(trichloromethyl) carbonate (C₃Cl₆O₃), diiodomethane (CH₂I₂), diiodoethane (C₂H₄I₂), acetyl chloride (CH₃COCl), oxalyl chloride (CO₂Cl₂), sulfur tetrafluoride (SF₄), sulfur hexafluoride (SF₆), sulfur dichloride (SCl₂), disulfur dichloride (S₂Cl₂), thionyl chloride (SOCl₂), sulfuryl chloride (SO₂Cl₂), xenon difluoride (XeF₂), selenium tetrafluroride (SeF₄), selenium hexafluroride (SeF₆), selenium dichloride (SeCl₂), selenium tetrachloride (SeCl₄), diselenium dichloride (Se₂Cl₂), tellurium hexafluoride (TeF₆), silicon tetrachloride (SiCl₄), antimony pentafluoride (SbF₅), antimony trichloride (SbCl₃), antimony pentachloride (SbCl₅), boron trichloride (BCl₃), germanium tetrachloride (GeCl₄), nitrogen trifluoride (NF₃), nitrogen chloride fluoride (NCl₂F and/or NF₂Cl), nitrosyl fluoride (NOF), nitryl fluoride (NO₂F), phosphorous trichloride (PCl₃), phosphorous pentachloride (PCl₅), phosphoryl chloride (POCl₃), phosphorous tribromide (PBr₃), phosphorous pentabromide (PBr₅), phosphoryl bromide (POBr₃), hydrogen fluoride (HF), hydrogen chloride (HCl), fluorine (F₂), chlorine (Cl₂), bromine (Br₂), and a metal halide. Example metal halides include, but are not limited to, titanium tetrafluoride (TiF₄), titanium tetrachloride (TiCl₄), tungsten hexafluoride (WF₆), niobium pentafluoride (NbF₅), and niobium pentachloride (NbCl₅). In some embodiments, the halogen reactant comprises chlorine. In some embodiments, the substrate is exposed to the halogen reactant under thermal conditions. In other words, the halogen reactant is free of plasma species and the substrate is not exposed to plasma species (e.g., ionic species, radical species, atoms, metastable species, and/or excited species). In other embodiments, the halogen reactant is supplied through a plasma source to form plasma species. In some of these embodiments, the halogen reactant comprises a plasma species.

In some embodiments, the halogen reactant is introduced into the reaction space after introduction of the metal precursor, prior to introducing the phosphorous precursor (e.g., see 203 in FIG. 2 and 305 in FIG. 3). In these embodiments, the metal and phosphorus containing film may be formed via a three-step process. Without wishing to be bound by a particular mechanism, it is hypothesized that the halogen reactant coverts the ligand(s) of the adsorbed metal precursor to halide ligand(s) via an exchange reaction, thereby increasing the reactivity of the adsorbed metal precursor towards certain phosphorous precursors. This three-step process may be particularly useful where there is no suitable metal halide metal precursor available. For example, many metal halides are solids and do not have sufficient vapor pressure and/or sufficient thermal stability to use in vapor deposition processes. This is the case for rare earth metal halides and many other metal halides. Using a halide ligand exchange reaction, allows for the formation of a surface adsorbed metal halide precursor, which may then facilitate a subsequent reaction with certain phosphorous precursors, such as, for example trisilylphosphine (P(SiH₃)₃), tris trimethylsilyl)phosphine (P(SiMe₃)₃), tris(triethylsilyl)phosphine (P(SiEt₃)₃), and tris(triisopropylsilyl)phosphine (P(SiᵢPr₃)₃).

In other embodiments, the halogen reactant may be used to remove certain impurities (e.g., carbon and/or oxygen) from the metal and phosphorous containing film. For example, the halogen reactant may be used to reduce the amount of carbon, nitrogen, oxygen, and/or elemental phosphorus impurities in the film, by reacting with the impurities to form volatile reaction products, thereby improving the quality of the metal and phosphorous containing film. In these embodiments, the halogen reactant may be introduced into the reaction space at the end of the cyclic deposition process, as a final step; or intermittently or periodically in the cyclic deposition (e.g., see 203 in FIG. 2; 305 in FIG. 3; 405 in FIG. 4; 603 in FIG. 6; 705 in FIG. 7, and 805 or 807 in FIG. 8).

In certain embodiments, the substrate is exposed to an oxygen reactant. The oxygen reactant is introduced into the reaction space and at least a portion of the surface of the substrate is contacted with the oxygen reactant. Suitable oxygen reactants include, but are not limited to, oxygen (O₂), ozone (O₃), water (H₂O), deuterated water (D₂O), hydrogen peroxide (H₂O₂), an organic peroxide (ROOH, where R is an alkyl or an aryl group), an alcohol (ROH, where R is an alkyl or an aryl group), nitrogen dioxide (NO₂), nitrous oxide (N₂O), nitric oxide (NO), dinitrogen pentoxide (N₂O₅), pyridine oxide (C₅H₅NO), an amine oxide (R₃NO, where each R is independently an alkyl group or an aryl group, and/or two or more R groups may be bonded to one another to form a ring structure), and combinations thereof. In some embodiments, the oxygen containing reactant is oxygen, ozone, nitrous oxide, or a combination thereof. In some embodiments, the substrate is exposed to the oxygen reactant under thermal conditions. In other words, the oxygen reactant is free of plasma species and the substrate is not exposed to plasma species (e.g., ionic species, radical species, atoms, metastable species, and/or excited species). In other embodiments, the oxygen reactant is supplied through a plasma source to form plasma species. In some of these embodiments, the oxygen reactant comprises a plasma species.

Another aspect of the present disclosure is related to systems for forming the metal and phosphorus containing films disclosed herein, using the methods disclosed herein. The system for forming the metal and phosphorus containing films may be used to form a structure comprising a threshold voltage shifting layer comprising a metal and phosphorus containing material. In some embodiments, the system is a semiconductor processing apparatus that comprises a reaction space (i.e., at least one reaction chamber) for accommodating a substrate. The semiconductor processing apparatus may comprise one reaction chamber, two reaction chambers, three reaction chambers, four reaction chambers, or more. In some embodiments, semiconductor processing apparatus is a cluster tool. In some embodiments, a reaction chamber or reaction chambers in a flow-type reactor may be utilized. In some embodiments, a reaction chamber or reaction chambers in a showerhead-type reactor may be utilized. In some embodiments, a reaction chamber or reaction chambers in a space divided reactor may be utilized. In some embodiments, a reaction chamber or reaction chambers in a high-volume manufacturing-capable single wafer reactor may be utilized. In other embodiments, a reaction chamber or reaction chambers in a batch reactor may be utilized. The semiconductor processing apparatus further comprises a means for exposing at least a portion of the surface of the substrate to a metal precursor and a phosphorous precursor and optionally a means for purging the reaction space between the exposing steps. The semiconductor processing apparatus may further comprise a means for optionally exposing at least a portion of the surface of the substrate to a halogen reactant and/or an oxygen reactant.

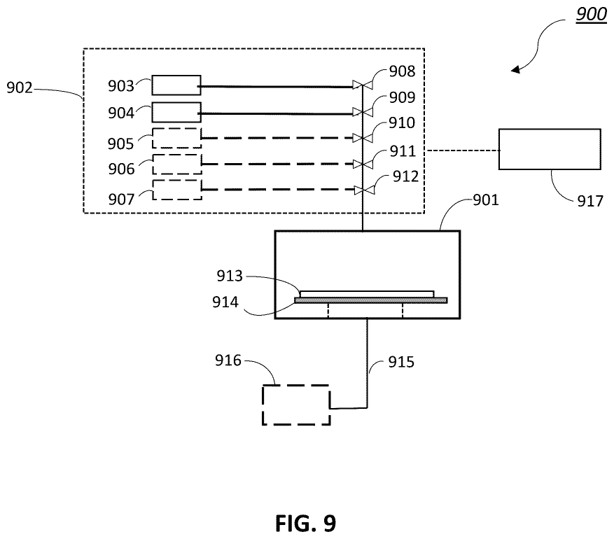

FIG. 9 shows a schematic diagram of an exemplary embodiment of a semiconductor processing apparatus 900 according to the present disclosure. Gaseous reactants are provided into a reaction space 901 through an injector system 902. The injector system 902 is configured to provide a metal precursor from a metal precursor source 903 that is coupled to a metal precursor source valve 908, a phosphorous precursor from phosphorous precursor source 904 that is coupled to a phosphorous precursor source valve 909, optionally a halogen reactant from a halogen reactant source 905 that is coupled to a halogen reactant source valve 910, and optionally an oxygen reactant from an oxygen reactant source 906 that is coupled to an oxygen source valve 911. The injector system 902 may further comprise one or more other gases sources from a source 907, for example, for providing purge gases and carrier gases (e.g., nitrogen and/or a noble gas, such as He, Ne, Ar, Kr, Xe, and combinations thereof) to the reaction space 901, and a means for heating the various reactant sources and corresponding gas lines (not shown), if required, to facilitate their introduction into the reaction space 901. The various gasses flow into the reaction space 901 that houses a substrate 913 positioned on a susceptor 914. In FIG. 9 the various gasses flow into the reaction space 901 from the top of the reaction space above the substrate 913; however, one of skill in the art will recognize that other flow configurations and/or other mechanisms for housing the substrate may be utilized. In some embodiments, the reaction space further comprises one or more heating elements (not shown) that are in thermal communication with the substrate 913 and one or more thermocouples (not shown), to measure and maintain a temperature of the substrate 913 at a set temperature. Unreacted gasses and gaseous reaction by-products exit the reaction chamber 901 through an exhaust line 915 that is optionally coupled to a vacuum pump 916. The semiconductor processing apparatus also comprises a controller 917 operably connected to the components of the injector system 902, for example, the metal precursor source valve 908 and the phosphorous precursor source valve 909, and the optional the halogen reactant source valve 910 and the oxygen reactant source valve 911, and other components (not shown). The controller 917 is configured and programmed to independently control (e.g., turn on and off, etc.) the supply of the various gasses (e.g., the metal precursor, the phosphorous precursor, the optional halogen reactant, the optional oxygen reactant, and optional carrier gasses and purging gasses, etc.), and other components, as required, to form the metal and phosphorous containing film on at least a portion of a surface of the substrate 913.

In some embodiments, the controller 917 is configured and programed to perform at least one deposition cycle of a cyclic deposition process (for example, according to FIG. 1) comprising a first operation and a second operation, among other things. In the first operation, the controller 917 opens the metal precursor source valve 908 to flow the metal precursor from the metal precursor source 903 into the reaction space 901, thereby exposing at least a portion of a surface of the substrate to the metal precursor and, after a set period of time, the controller 907 closes the metal precursor source valve 908 to the metal precursor source 903. In the second operation, the controller 917 opens the phosphorous precursor source valve 909 to flow the phosphorous precursor from the phosphorous precursor source 904 into the reaction space 901, thereby exposing the at least a portion of the surface of the substrate to the phosphorous precursor and, after a set period of time, the controller 917 closes the phosphorous precursor source valve 909 to the phosphorous precursor source 904. In certain embodiment, the controller 917 is programed to perform the first operation and the second operation, or vice versa, wherein at least a portion of the first operation overlaps with at least a portion of the second operation such that the flow of the metal precursor into the reaction space 901 at least partially overlaps with the flow phosphorous precursor into the reaction space 901 to form a metal and phosphorous containing film on the at least a portion of the surface of the substrate 913. In certain other embodiments, the controller 917 is programed to sequentially perform the first operation followed by the second operation, or vice versa, such that the flow of the metal precursor into the reaction space 901 and the flow phosphorous precursor into the reaction space 901 do not overlap, one or more n times to form a metal and phosphorous containing film on the at least a portion of the surface of the substrate 913.

In other embodiments, the controller 917 is configured and programed to perform at least one deposition cycle of a cyclic deposition process (for example, according to FIG. 2, FIG. 3, or FIG. 4) comprising a first operation, a second operation, and an optional third operation, among other things. In the first operation, the controller 917 opens the metal precursor source valve 908 to flow the metal precursor from the metal precursor source 903 into the reaction space 901, thereby exposing at least a portion of a surface of the substrate to the metal precursor and, after a set period of time, the controller 907 closes the metal precursor source valve 908 to the metal precursor source 903. In the second operation, the controller 917 opens the phosphorous precursor source valve 909 to flow the phosphorous precursor from the phosphorous precursor source 904 into the reaction space 901, thereby exposing the at least a portion of the surface of the substrate to the phosphorous precursor and, after a set period of time, the controller 917 closes the phosphorous precursor source valve 909 to the phosphorous precursor source 904. In the third operation, the controller 917 opens halogen reactant source valve 910 to flow the halogen reactant from the halogen reactant source 905 into the reaction space 901, thereby exposing the at least a portion of the surface of the substrate to the halogen reactant and, after a set period of time, the controller 917 closes the halogen reactant source valve 910 to the halogen reactant source 905. In certain embodiments, the controller 917 is programed to sequentially perform the first operation, the third operation, and the second operation one or more n times to form a metal and phosphorous containing film on the at least a portion of the surface of the substrate 913 (e.g., see FIG. 2); or, alternatively, the controller 917 is programed to sequentially perform the second operation, the first operation, and the third operation one or more n times to form a metal and phosphorous containing film on the at least a portion of the surface of the substrate 913 (e.g., see FIG. 3). In certain other embodiments, the controller 917 is programed to sequentially perform the first operation followed by the second operation, or vice versa, one or more n times and to perform the third operation at least once and optionally one or more m times to form a metal and phosphorous containing film on the at least a portion of the surface of substrate 913 (e.g., see FIG. 4). In some instances, the number of times that the third operation is performed (m) may be equal to the number times that the first and second operations are performed (n) (i.e., m=n). In other instances, the number of times that the third operation is performed (m) may be less than the number times that the first and second operations are performed (n) (i.e., m<n). For example, the third operation may be performed every other deposition cycle, or every few deposition cycles, or only once at the end of the cyclic deposition process as a final step (i.e., m=0).

In yet other embodiments, the controller 917 is configured and programed to perform at least one deposition cycle of a cyclic deposition process (for example, according to FIG. 5) comprising a first operation, a second operation, and an optional third operation, among other things. In the first operation, the controller 917 opens the metal precursor source valve 908 to flow the metal precursor from the metal precursor source 903 into the reaction space 901, thereby exposing at least a portion of the surface of the substrate to the metal precursor and, after a set period of time, the controller 907 closes the metal precursor source valve 908 to the metal precursor source 903. In the second operation, the controller 917 opens the phosphorous precursor source valve 909 to flow the phosphorous precursor from the phosphorous precursor source 904 into the reaction space 901, thereby exposing at least a portion of the surface of the substrate to the phosphorous precursor and, after a set period of time, the controller 917 closes the phosphorous precursor source valve 909 to the phosphorous precursor source 904. In the third operation, the controller 917 opens the oxygen reactant source valve 911 to flow the oxygen reactant from the oxygen reactant source 906 into the reaction space 901, thereby exposing at least a portion of the surface of the substrate to the oxygen reactant and, after a set period of time, the controller 917 closes the oxygen reactant source valve 911 to the oxygen reactant source 906. In some embodiments, the controller 917 is programed to sequentially perform the first operation followed by the second operation, or vice versa, one or more n times and to perform the third operation at least once an optionally one or more m times to form a metal and phosphorous containing film that further comprises oxygen on the surface of the substrate 913. In some instances, the number of times that the third operation is performed (m) may be equal to the number times that the first and second operations are performed (n) (i.e., m=n). In other instances, the number of times that the third operation is performed (m) may be less than the number times that the first and second operations are performed (n) (i.e., m<n). For example, the third operation may be performed every other deposition cycle, or every few deposition cycles, or only once at the end of the cyclic deposition process (i.e., m=0).

As will be appreciated by one of skill in art, the controller may be configured and programed to perform other embodiments of the disclosure, such as, for example those shown in FIG. 6, FIG. 7, and FIG. 8. Likewise, the controller 917 may be further configured and programed to perform other operations. For example, the controller 917 may be operably connected to a purge gas source 907 and configured and programed to open a valve 912 to the purge gas source to flow a purge gas into the reaction space 901 and, after a set period of time, close the valve 912 to the purge gas. In another example, the controller 917 may be operably connected to one or more heating elements (not shown) and one or more thermocouples (not shown) and configured and programed to measure and control a temperature of the at least one heating element to maintain a temperature of the substrate 913 at a set temperature.

In some embodiments, a system for forming a metal and phosphorous containing film on at least a portion of a surface of a substrate comprises: a reaction space for accommodating a substrate; a metal precursor source for providing a metal precursor in gas communication via a metal precursor source valve with the reaction space; a phosphorous precursor source for providing a phosphorus precursor in gas communication via a phosphorous precursor source valve with the reaction space; and a controller operably connected to the metal precursor source valve and the phosphorous precursor source valve configured and programmed to perform the methods disclosed herein. The controller may be configured and programmed to sequentially control: opening one of the metal precursor source valve to the metal precursor source and the phosphorous precursor source valve to the phosphorous precursor source; closing the one of the metal precursor source valve to the metal precursor source and the phosphorous precursor source valve to the phosphorous precursor source; opening the other of the metal precursor source valve to the metal precursor source and the phosphorous precursor source valve to the phosphorous precursor source; and closing the other of the metal precursor source valve to the metal precursor source and the phosphorous precursor source valve to the phosphorous precursor source. For example, the controller may be configured and programmed to perform at least one deposition cycle of a cyclic deposition process comprising sequentially controlling: opening the metal precursor source valve to the metal precursor source to supply the metal precursor into the reaction space; closing the metal precursor source valve to the metal precursor source to cease the supply the metal precursor into the reaction space; opening the phosphorous precursor source valve to the phosphorous precursor source to supply the phosphorus precursor into the reaction space; and closing the phosphorous precursor source valve to the phosphorous precursor source to cease the supply of the phosphorus precursor into the reaction space. Additionally, or alternatively, the controller may be configured and programmed to perform at least one deposition cycle of a cyclic deposition process comprising sequentially controlling: opening the phosphorous precursor source valve to the phosphorous precursor source to supply the phosphorus precursor into the reaction space; closing the phosphorous precursor source valve to the phosphorous precursor source to cease the supply of the phosphorus precursor into the reaction space; opening the metal precursor source valve to the metal precursor source to supply the metal precursor into the reaction space; and closing the metal precursor source valve to the metal precursor source to cease the supply the metal precursor into the reaction space. The controller may be further programed to sequentially repeat the opening of the metal precursor source valve to the metal precursor source, then the closing of the metal precursor source valve to the metal precursor source and the opening of the phosphorous precursor source valve to the phosphorous precursor source, then the closing of the phosphorous precursor source valve to the phosphorous precursor source, or vice versa, to form a metal and phosphorous containing film on the at least a portion of the surface of the substrate.

In some embodiments, the system further comprises a halogen reactant source for providing halogen reactant in gas communication via a halogen reactant source valve with the reaction space and the controller is further operably connected to the halogen reactant source valve and configured and programmed to control: opening the halogen reactant source valve to the halogen reactant source to supply the halogen reactant into the reaction space; and closing the halogen reactant source valve to the halogen reactant source to cease the supply of the halogen reactant into the reaction space. In certain embodiments, the controller is further programed to, after each of the closing of the metal precursor source valve to the metal precursor source, open the halogen reactant source valve to the third and then close the halogen reactant source valve to the halogen reactant source. In certain other embodiments, the controller is further programed to, after at least one of the closing of the metal precursor source valve to the metal precursor source or after at least one of the closing of the phosphorous precursor source valve to the phosphorous precursor source, open the halogen reactant source valve to the halogen reactant source and close the halogen reactant source valve to the halogen reactant source. In certain other embodiments, the controller is further programed to, after a final step of the closing of the metal precursor source valve to the metal precursor source or after a final step of the closing of the phosphorous precursor source valve to the phosphorous precursor source, open the halogen reactant source valve to the halogen reactant source and close the halogen reactant source valve to the halogen reactant source.

In some embodiments, the system further comprises an oxygen reactant source for providing an oxygen reactant in gas communication via an oxygen reactant source valve with the reaction space and the controller is further operably connected to the oxygen reactant source valve and configured and programmed to control: opening the oxygen reactant source valve to the oxygen reactant source to supply the oxygen reactant into the reaction space; and closing the oxygen reactant source valve to the oxygen reactant source to cease the supply of the oxygen reactant into the reaction space. In certain embodiments, the controller is further programed to, after at least one of the closing of the metal precursor source valve to the metal precursor source or after at least one of the closing of the phosphorous precursor source valve to the phosphorous precursor source, open the oxygen reactant source valve to the oxygen reactant source and close the oxygen reactant source valve to the oxygen reactant source. In certain other embodiments, the controller is further programed to, after every of the closing of the metal precursor source valve to the metal precursor source or the closing of the phosphorous precursor source valve to the phosphorous precursor source, open the oxygen reactant source valve to the oxygen reactant source and close the oxygen reactant source valve to the oxygen reactant source. In certain other embodiments, the controller is further programed to, after a final step of the closing of the metal precursor source valve to the metal precursor source or after a final step of the closing of the phosphorous precursor source valve to the phosphorous precursor source, open the oxygen reactant source valve to the oxygen reactant source and close the oxygen reactant source valve to the oxygen reactant source.

Another aspect of the disclosure is related to semiconductor device structures comprising the metal and phosphorus containing films disclosed herein, formed using the methods and systems disclosed herein. In particular, the metal and phosphorus containing films may be used as a threshold voltage shifting layer in a semiconductor device structure, such as a FET. The use of the metal and phosphorous containing film as a threshold voltage shifting layer results in a shift in the effective work function of the gate electrode in the FET towards the Si conduction band in the case of n-type FETs or towards the Si valence band in the case of p-type FETs. According to some embodiments of the present disclosure, a gate stack comprising a threshold voltage shifting layer comprising the metal and phosphorus containing material disclosed herein can have an effective work from ranging from about 4.0 eV to about 5.1 eV, wherein the shift in the effective work function is about 10 meV to about 400 meV, or about 30 meV to about 300 meV, or about 50 meV to about 200 meV. The thickness of the threshold voltage shifting layer comprising the metal and phosphorus containing material can be tailored to tune the shift in the effective work function and hence the Vt. Accordingly, in various embodiments, a thickness of the threshold voltage shifting layer comprising the metal and phosphorus containing material may vary between about 0.01 nm and about 2 nm. In some embodiments, the thickness is about 2 nm or less, or about 1.9 nm or less, or about 1.8 nm or less, or about 1.7 nm or less, or about 1.6 nm or less, or about 1.5 nm or less, or about 1.4 nm or less, or about 1.3 nm or less, or about 1.2 nm or less, or about 1.1 nm or less, or about 1 nm or less, or about 0.9 nm or less, or about 0.8 nm or less, or about 0.7 nm or less, or about 0.6 nm or less, or about 0.5 nm or less, or about 0.4 nm or less, or about 0.3 nm or less, or about 0.2 nm or less, or about 0.1 nm or less. In some embodiments, the thickness is about 2 nm, or about 1.9 nm, or about 1.8 nm, or about 1.7 nm, or about 1.6 nm, or about 1.5 nm, or about 1.4 nm, or about 1.3 nm, or about 1.2 nm, or about 1.1 nm, or about 1 nm, or about 0.9 nm, or about 0.8 nm, or about 0.7 nm, or about 0.6 nm, or about 0.5 nm, or about 0.4 nm, or about 0.3 nm, or about 0.2 nm, or about 0.1 nm, or any intermediate thickness between about 0.01 nm and about 2 nm or a narrower range of any two thickness within. Additionally, the composition of the threshold voltage shifting layer comprising the metal and phosphorus containing material can be tailored to tune the shift in the effective work function and hence the Vt, and/or to reduce the EOT of the layer. Accordingly, in some embodiments, the threshold voltage shifting layer comprising the metal and phosphorus containing material has a low oxygen content or is free of oxygen. Additionally, or alternatively, in some embodiments, the threshold voltage shifting layer comprising the metal and phosphorus containing material has one or more of a low carbon content and a low elemental phosphorus content, thereby beneficially reducing the number of defects in the layer.

In some embodiments, the semiconductor device structure comprises a substrate; a gate dielectric comprising a high-κ dielectric layer positioned on at least a portion of a surface of the substrate; and a threshold voltage shifting layer comprising a metal and phosphorus containing material, wherein the threshold voltage shifting layer is positioned on the at least a portion of a surface of the substrate either underneath the high-κ dielectric layer or over the high-κ dielectric layer. The high-κ dielectric layer may comprise a high-κ material that has a dielectric constant that is larger than that of silicon oxide, generally higher than about 7. Non-limiting examples of high-κ materials include hafnium oxide (HfO₂), tantalum oxide (Ta₂O₅), zirconium oxide (ZrO₂), titanium oxide (TiO₂), hafnium silicate (HfSiOₓ), aluminum oxide (Al₂O₃), lanthanum oxide (La₂O₃), and combinations and mixtures thereof. Additionally, or alternatively, the semiconductor device structure may comprise an interlayer (or an interfacial layer) positioned on the at least a portion of the surface of the substrate below the high-κ dielectric layer and the threshold voltage shifting layer. The interlayer may comprise silicon dioxide, silicon oxynitride, germanium oxynitride, tantalum oxynitride, or another suitable material. Additionally, or alternatively, the semiconductor device structure may further comprise a metal layer positioned on the at least a portion of the surface of the substrate over the threshold voltage shifting layer and over the high-κ dielectric layer. The semiconductor device structure can be or form part of a MOSFET and in some instances form part of a CMOS device. In some embodiments, the semiconductor device structure may be an intermediate structure, for example an intermediate MOSFET structure. In this context, “intermediate” refers to a structure that is partially formed and further production steps are required to form the final structure.

The semiconductor device structures comprising a metal and phosphorus containing film may be formed using the methods disclosed herein. A method for forming a semiconductor device structure comprising a threshold voltage shifting layer, comprises providing a substrate in a reaction space (i.e., one or more reaction chambers) and depositing a metal and phosphorus containing layer on at least a portion of a surface of the substrate using the methods disclosed herein. More specifically, a method for forming a semiconductor device structure comprising a threshold voltage shifting layer comprises, providing a substrate in a reaction space (i.e., one or more reaction chambers) and performing at least one deposition cycle of a cyclic deposition process comprising, sequentially exposing at least a portion of a surface of the substrate to a metal precursor and to a phosphorous precursor, thereby forming a threshold voltage shifting layer comprising a metal and phosphorus containing material on the at least a portion of the surface of the substrate. In some embodiments, the method for forming a semiconductor device structure comprising a threshold voltage shifting layer comprises, providing a substrate in a reaction space and performing a cyclic deposition process according to the process shown in any one of FIG. 1, FIG. 2, FIG. 3, FIG. 4, FIG. 5, FIG. 6, FIG. 7, and FIG. 8, and discussed above, thereby forming threshold voltage shifting layer comprising a metal and phosphorus containing material on the at least a portion of the surface of the substrate. In some of these embodiments, the substrate comprises an interlayer and the metal and phosphorus containing layer is formed on or over at least a portion of the interlayer, in some instance the metal and the phosphorus containing layer is formed directly on or over at least a portion of the interlayer. In some embodiments, the substrate comprises a high-κ dielectric layer and the metal and the phosphorus containing layer is formed on or over at least a portion of the high-κ layer, in some instance the metal and the phosphorus containing layer is formed directly on or over at least a portion of the high-κ layer. In some embodiments, the substrate comprises one or more work function layers or metal layers and the metal and the phosphorus containing layer is formed on or over at least a portion of the one or more work function layers or metal layers, in some instance the metal and the phosphorus containing layer is formed directly on or over at least a portion of one of the one or more work function layers or metal layers. In some embodiments, the method further comprises, annealing the substrate. The annealing may be performed by heating the substrate comprising the metal and phosphorous containing film to an annealing temperature from at least about 300° C. to no more than about 1,000° C. for a set period of time, typically from at least about 300° C. to no more than about 600° C. or from about at least about 600° C. to no more than about 1,000° C. In particular, a high temperature anneal (e.g., a drive-in anneal) may be performed as part of gate last manufacturing to drive the metal and phosphorous containing layer and/or other material layers on the substrate into one or more of an insulating layer, an interlayer, or a high-κ dielectric layer.

The method for forming a semiconductor device structure comprising a threshold voltage shifting layer that comprises a metal and phosphorus containing material can be performed using the systems disclosed herein. In some embodiments, the method for forming a semiconductor device structure comprising a metal and phosphorus containing film is performed in one or more reaction chambers of a semiconductor cluster tool. In some embodiments, the method may be performed in a reaction chamber of a semiconductor cluster tool according to the system shown in FIG. 9. Other process steps required to form the structure may be performed in the other reaction chambers of the same cluster tool. For instance, the semiconductor cluster tool may additionally comprise one or more of a reaction chamber for forming an interlayer, a reaction chamber for forming a high-κ dielectric layer, and a reaction chamber for forming a metal layer.

Although certain embodiments and examples are disclosed herein, it will be understood by those skilled in the art that the disclosed compositions, methods, systems, and structures extend beyond the specifically disclosed embodiments and include all novel and nonobvious combinations and sub-combinations of the various compositions, methods, systems, and structures, as well as any and all equivalents thereof. It is to be understood that the compositions, methods, systems, and structures described herein are exemplary in nature, and that these specific embodiments or examples are not to be considered in a limiting sense, because numerous variations are possible. The specific methods and systems described herein may represent one or more of any number of processing strategies. Thus, the various acts illustrated may be performed in the sequence illustrated, in other sequences, or omitted in some cases. Moreover, various features of the disclosure are grouped together in one or more, aspects, embodiments, and configurations for the purpose of streamlining the disclosure. The features of the aspects, embodiments, and configurations of the disclosure may be combined in alternate aspects, embodiments, and configurations other than those discussed above. The compositions, methods, systems, and structures of the disclosure are not to be interpreted as reflecting an intention that the claimed disclosure requires more features than are expressly recited in each claim. Rather, as the following claims reflect, inventive aspects lie in less than all features of a single foregoing disclosed aspects, embodiments, and configurations. Thus, the following claims are hereby incorporated into this Detailed Description, with each claim standing on its own as a separate embodiment of the disclosure, and the features recited in the various dependent claims may be combined with one another in various combinations, as appropriate, to form other embodiment of the disclosure.

1. A method of forming a semiconductor device structure comprising a threshold voltage shifting layer, the method comprising:
a. providing a substrate in a reaction space; and
b. executing one or more deposition cycles of a cyclic deposition process comprising:
i. exposing at least a portion of a surface of the substrate to one of a metal precursor and a phosphorus precursor; and
ii. exposing the at least a portion of the surface of the substrate to the other of the metal precursor and the phosphorus precursor, thereby forming a threshold voltage shifting layer on the at least a portion of the surface of the substrate,
wherein the threshold voltage shifting layer comprises a metal and phosphorous containing material comprising a metal selected from the group consisting of a rare earth metal, a group 4 metal, a group 6 metal, a group 13 metal, and combinations thereof.

2. The method according to claim 1, wherein the substrate comprises at least one of an interlayer and a high-κ dielectric layer.

3. The method according to claim 2, wherein the substrate comprises the interlayer and the threshold voltage shifting layer is formed on the interlayer.

4. The method according to claim 2, wherein the substrate comprises the high-κ dielectric layer and the threshold voltage shifting layer is formed on the high-κ dielectric layer.

5. The method according to claim 1, wherein the method further comprises annealing the substrate.

6. The method according to claim 1, wherein the threshold voltage shifting layer has a thickness of about 1 nm or less.

7. The method according to claim 1, wherein at least one of the one or more deposition cycles of the cyclic deposition process further comprises exposing the at least a portion of the surface of the substrate to a halogen reactant, wherein the exposing of the at least a portion of the surface of the substrate to the halogen reactant occurs after the exposing of the at least a portion of the surface of the substrate to the metal precursor.

8. The method according to claim 1, wherein the metal and phosphorus containing material is substantially free of oxygen.

9. The method according to claim 1, wherein at least one of the one or more deposition cycles of the cyclic deposition process further comprises: exposing the at least a portion of the substrate to an oxygen reactant, wherein the metal and phosphorus material further comprises oxygen.

10. The method according claim 1, wherein the metal and phosphorus containing material comprises a rare earth metal phosphide selected from the group consisting of scandium phosphide, yttrium phosphide, lanthanum phosphide, cerium phosphide, and combinations thereof.

11. The method according claim 1, wherein the metal and phosphorus containing material comprises a group 4 metal phosphide selected from the group consisting of titanium phosphide, zirconium phosphide, hafnium phosphide, and combinations thereof.

12. The method according to claim 1, wherein the metal and phosphorus containing material comprises a group 6 metal phosphide selected from the group consisting of chromium phosphide, molybdenum phosphide, tungsten phosphide, and combinations thereof.

13. The method according to claim 1, wherein the metal and phosphorus containing material comprises a group 13 metal phosphide selected from the group consisting of boron phosphide, aluminum phosphide, gallium phosphide, indium phosphide, and combinations thereof.

14. The method according claim 1, wherein the metal precursor comprises a metal and one or more ligands selected from the group consisting of a halide, a carbonyl, an oxo, an alkyl, a cyclopentadienyl, η⁶-arene, an alkoxide, an imido, an alkyl amide, a silyl amide, a β-diketonate, an amidinate, a diazadiene, and a triazenide.

15. The method according to claim 1, wherein the cycle deposition process is performed under thermal conditions and wherein the method further comprises, maintaining a temperature of the substrate at a set temperature of no more than about 450° C. during the cyclic deposition process.

16. A method of forming a metal and phosphorus containing film, the method comprising:
a. providing a substrate in a reaction space; and
b. executing one or more deposition cycles of a cyclic deposition process comprising:
i. exposing at least a portion of a surface of the substrate to one of a metal precursor and a phosphorus precursor;
ii. purging the reaction space;
iii. exposing the at least a portion of the surface of the substrate to the other of the metal precursor and the phosphorus precursor; and
iv. purging the reaction space,
wherein a metal and phosphorus containing film is formed on the at least a portion of the surface of the substrate,
wherein the metal and phosphorus containing film comprises a metal phosphide material or a metal oxyphosphide material comprising a metal selected from the group consisting of a rare earth metal, titanium (Ti), zirconium (Zr), hafnium (Hf), niobium (Nb), tantalum (Ta), chromium (Cr), tungsten (W), and mixtures thereof.

17. The method according to claim 16, wherein the cyclic deposition process further comprises exposing the at least a portion of the surface of the substrate to a halogen reactant.

18. The method according to claim 16, wherein the cyclic deposition process further comprises exposing the at least a portion of the surface of the substrate to an oxygen reactant.

19. A semiconductor device structure comprising a threshold voltage shifting layer formed by means of the method according to claim 1.

20. A semiconductor processing apparatus comprising,
a reaction space for accommodating a substrate,
a metal precursor source for providing a metal precursor in gas communication via a metal precursor source valve with the reaction space;
a phosphorous precursor source for providing a phosphorous precursor in gas communication via a phosphorous precursor source valve with the reaction space;
an exhaust; and
a controller operably connected to the metal precursor source valve and the phosphorous precursor source valve,
wherein the controller is configured and programmed to perform the method according to claim 1.
